(19) United States
(12) Patent Application Publication
(10) Pub. No.: US 2026/0024683 A1
(43) Pub. Date: Jan. 22, 2026

(54) COMPOSITE CONDUCTORS INCLUDING LOW RESISTANCE MATERIALS

(71) Applicant: TS Conductor Corp., Huntington Beach, CA (US)

(72) Inventor: Jianzhong Jason HUANG, San Clemente, CA (US)

(21) Appl. No.: 19/275,374

(22) Filed: Jul. 21, 2025

Related U.S. Application Data
(60) Provisional application No. 63/673,923, filed on Jul. 22, 2024.

(51) Int. Cl. H01B 12/06; H01B 1/04; H01B 1/08; H01B 9/00; H01B 9/04; H10N 60/85

(52) U.S. Cl. CPC H01B 12/06; H01B 9/006; H01B 9/04; H01B 1/04; H01B 1/08; H10N 60/857

(57) ABSTRACT

An apparatus comprises a strength member and a conductor layer disposed around the strength member. The strength member includes a core formed of a composite material, and an encapsulation layer disposed around the core. The conductor layer includes a low resistance material having a resistivity of less than 10⁻¹⁰ Ω·cm over an operating temperature in a range of from about −40 degrees Celsius to about 250 degrees Celsius. The conductor material may include a superconductor or superconductor like material.

### CROSS-REFERENCE TO RELATED APPLICATIONS

This application claims priority to and the benefit of U.S. Provisional Patent Application No. 63/673,923, filed Jul. 22, 2024, and entitled, “Composite Conductors Including Low Resistance Materials”, the entire disclosure of which is hereby incorporated by reference herein.

### TECHNICAL FIELD

The embodiments described herein relate generally to composite conductors including a strength member and a conductor layer disposed around the strength member for use in grid transmission and distribution applications.

### BACKGROUND

With the ever-increasing global demand for electricity, utilities are grappling with significant challenges in meeting the growing needs of power generation and distribution. One of the primary obstacles to reliable electricity distribution is ensuring the efficient delivery of electricity to end-users, primarily due to the limited capacity of the existing transmission and distribution infrastructure. Notably, the US electrical grid, which still relies on Aluminum Conductor Steel-Reinforced (ACSR) conductor technology developed in 1908, suffers from constrained current-carrying capacity (often referred to as ampacity) and suboptimal efficiency.

These challenges in energy transmission are further compounded by the demand for electricity from energy transition. The current power grids are undergoing an unprecedented transformation from their original designs, revolutionizing how energy has been generated, delivered, and consumed over the past century. This new era of energy integration includes the incorporation of renewable sources into distribution grids. However, renewable energy sources are typically situated in remote locations, resulting in an estimated future average energy travel distance of 800 miles—a factor contributing to substantial energy losses due to the substantial resistivity of conductor materials used in conventional conductor.

### SUMMARY

Embodiments described herein relate generally to systems and methods for electrical transmission using composite conductors and, in particular, to electrical conductors that include a strength member and a conductor layer including a low resistance material (e.g., a superconductor) disposed around the strength member. The low resistance material has a resistivity of less than 10⁻¹⁰ Ω·cm over an operating temperature in a range of from about −40 degrees Celsius to about 250 degrees Celsius. The strength member includes a core formed of a composite material, and an encapsulation layer disposed around the core.

In some embodiments, an apparatus includes: a strength member, including: a core formed of a composite material, and an encapsulation layer disposed around the core. A conductor layer is disposed on the strength member, the conductor layer including a low resistance material having a resistivity of less than 10⁻¹⁰ Ω·cm over an operating temperature in a range of from about −40 degrees Celsius to about 250 degrees Celsius. In some embodiments, the low resistance material includes a superconductor or superconductor like material.

In some embodiments, a method includes: forming a core including a composite material; disposing an encapsulation layer on the core to form a strength member, and disposing one or more layers on the strength member, at least one layer of the one or more layers including a conductor having a resistivity of less than 10⁻¹⁰ Ω·cm over an operating temperature in a range of about −40 degrees Celsius about 250 degrees Celsius.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several implementations in accordance with the disclosure and are therefore, not to be considered limiting of its scope, the disclosure will be described with additional specificity and detail through use of the accompanying drawings.

FIG. 1 is a schematic illustration of a conductor for use in grid electrical transmission that includes a conductive layer including a low resistance material and a strength member including a composite core, according to an embodiment.

FIG. 2 is a side cross-section view of a conductor including a conductive layer including a low resistance material and a strength member including a composite core, according to an embodiment; and FIG. 3 is a front cross-section view of the conductor of FIG. 2 taken along the line A-A in FIG. 2.

FIG. 4 is a side perspective view of a conductor that includes a conductive layer including a low resistance material and a strength member including a composite core that is conductive, according to an embodiment.

FIG. 5 is a side cross-section view of a conductor including a conductive layer that includes a low resistance material and a pressurizing layer, and a strength member including a composite core, according to an embodiment.

FIG. 6 is a schematic flow chart of a method for fabricating a conductor that includes a strength member, and a conductor layer disposed around the strength member, according to an embodiment.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

Embodiments described herein relate generally to systems and methods for electrical transmission using conductors including a low resistance material (e.g., a superconductor material) and, in particular, to electrical conductors that include a strength member and a conductor layer including a low resistance material disposed around the strength member. The low resistance material has a resistivity of less than 10⁻¹⁰ Ω·cm over an operating temperature in a range of from about −40 degrees Celsius to about 250 degrees Celsius. The strength member includes a core formed of a composite material, and an encapsulation layer disposed around the core. In some embodiments, a plurality of conductive elements may be included in the composite material causing the core to be conductive.

Combining a conductor layer including a low resistance material with a strength member described herein can offer several advantages in grid transmission and other applications, primarily by leveraging the unique properties of low resistance materials (e.g., superconductors or superconductor like material) while maintaining practicality and cost-effectiveness. Providing a strength member together with a conductor layer including a low resistance material causes the conductors described herein to have lower resistance, higher ampacity, and lower line losses relative to comparable conductors that do not have a low resistance material, while having low sag and high mechanical strength relative to comparable conductors that do not include the strength member.

The electrical grid is a major contributor to greenhouse emissions and global warming. The US electrical grid is more than 25 years old and globally about 2,000 TWh electricity is wasted annually, and about 1 Billion Metric Ton of GHG emission is associated with compensatory generation. As the demand for electricity grows, there is an increased demand for higher capacity electricity transmission and distribution lines. The amount of power delivered by an electrical conductor is dependent on the current-carrying capacity (also referred to as the ampacity) of the conductor transmitting the electric current.

The US electrical grid today is still dominated by the Aluminum Conductor Steel-Reinforced (ACSR) conductor technology developed in 1908. The ACSR conductor has limited capacity and poor efficiency and was the principal reason for bottlenecks to energy transmission observed in our electrical grid. In addition to the US electrical grid being old, the problems in energy transmission are further compounded by changing weather patterns, frequent extreme weathers and the demand for electricity from energy transition. The electrical grid infrastructure is built around fossil burning power plants, and electrical current (i.e., electrons) only need to travel on average of 200 miles or less. With renewable electrical energy generation being located typically in remote locations, the average travel distance for electrical energy is estimated to be 800 miles in the future. A recent research report forecasted a 50% EV adoption by 2035 in California, which will create significant pressure on distribution grid to support the charging infrastructure at least in that state. Thus, there is a need for new conductor technologies that have lower resistance, higher ampacity, and lower line losses.

As described herein, “low resistance materials” refers to materials that have a resistivity of less than 10⁻¹⁰ Ω·cm at an operating temperature or an operating temperature range.

As described herein, the term “superconductors” refers to materials that exhibit zero (or close to zero) resistance to electrical currents as well as perfect diamagnetism (the Meissner Effect), under certain conditions such as below a critical temperature (T_{c}). The resistivity of a superconductor is typically measured to be less than 4×10⁻²² Ω·cm below their critical temperature T_{c}.

As describe herein, the term “superconductor like materials” refers to materials that have resistivity similar to superconductors but do not possess all the properties of superconductors such as do not possess perfect diamagnetism.

The phenomenon of superconductivity is exemplified by the Meissner effect, which results in the complete expulsion of magnetic field lines from the interior of the superconductor when it transitions into its superconducting state. Conventional superconductors or materials that display superconducting properties typically have critical temperatures below 30 K (minus 243 degrees Celsius). A superconductor is classified as a high-temperature superconductor if it reaches a superconducting state at a temperature that can be achieved using liquid nitrogen, which corresponds to a critical temperature above 77 K (minus 196 degrees Celsius). However, this is still an extremely low temperature and not suitable for practical applications, particularly grid transmission applications where operating temperatures can exceed 200 degrees Celsius.

Superconductivity is a highly correlated electronic state of conducting solids that exhibits zero resistance and excludes magnetic flux (which is called Meissner Effect). Isolated electrons repel each other, and this repulsion is due to the Coulomb interaction which is usually negative. Superconductivity involves the formation of pairs of electrons (called Cooper Pairs). Superconductivity emerges when certain materials are cooled below a critical temperature, allowing electrons to form Cooper pairs. These pairs consist of two electrons with opposite spins and momenta, drawn together by an attractive force mediated by lattice vibrations. In this cooperative state, Cooper pairs move through the material without scattering, resulting in zero electrical resistance. Simultaneously, they expel magnetic flux lines from the interior of the superconductor, creating the Meissner effect, and manifesting perfect diamagnetism. Crucially, Cooper pairs exhibit an energy gap between their ground state and excited states, requiring a specific energy input to disrupt the superconducting state. Superconductivity, governed by these quantum pairs, enables materials to conduct electricity with unparalleled efficiency.

Above the critical temperature (T_{c}) in a conventional superconductor, thermal energy disrupts the coherence of Cooper pairs such that Cooper pairs do not exist in their usual, tightly bound state. The thermal energy causes the electrons in the pairs to gain kinetic energy, and they start to move more independently rather than staying tightly correlated as a Cooper pair. As a result, the superconducting state breaks down, and the material reverts to a normal, resistive state. In this normal state, electrons move individually, experiencing electrical resistance, and magnetic fields can penetrate the material.

Superconductors or superconductor like materials offer high throughput with low electric losses and have the potential to revolutionize the electric power grid. Implementing transmission networks with these advanced cables could, for instance, enable greater power delivery while facilitating substantial energy conservation.

Embodiments of the conductors described herein that include a strength member having a composite core and an encapsulation layer, and a conductor layer including a low resistance material that is disposed around the strength member, may provide one or more benefits including, for example: 1) providing a conductor layer that includes a low resistance material (e.g., a superconductor or superconductor like material) having a resistivity of less than 10⁻¹⁰ Ω·cm at room temperature, and can maintain this low resistivity at an operating temperature of the conductor in a range of from about −40 degrees Celsius to about 250 degrees Celsius; (2) reducing heat generation that mitigates energy loss as well maintains the composite core below its glass transition or melting temperature; (3) enhancing current-carrying capacity over conventional ACSR, Aluminum Conductor Steel Supported (ACSS) conductor, bare conductors, or conductors featuring composite core(s) that do not include a low resistance material (e.g., a superconductor); (4) improving electromagnetic compatibility; (5) allowing improved electrical characteristics, and additionally providing mechanical reinforcement to the conductor; (6) enabling increasing line capacity by simply replacing conventional conductors in the electrical grid with the conductors including the low resistance materials described herein; (7) protecting the composite core of the strength member from moisture and/or solvents that may damage the composite core by providing the encapsulation layer therearound; (8) improving performance of the conductors without impacting functionality, reliability, and/or performance of the conductor; and (9) enabling efficient long-distance power transmission.

As used herein, the singular forms “a”, “an” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

As described herein, the term “ambient pressure” refers to pressure of the environment in which the apparatus described herein are located. As appreciated, in most operational conditions, ambient pressure will be that pressure at ground level that is approximately 14.7 psi (101.3 kPa) at sea level.

As described herein, the terms “coupled,” and the like as used herein mean the joining of two members directly or indirectly to one another. Such joining may be stationary (e.g., permanent) or moveable (e.g., removable, or releasable). Such joining may be achieved with the two members, or the two members and any additional intermediate members being integrally formed as a single unitary body with one another or with the two members or the two members and any additional intermediate members being attached to one another.

As described herein, the term “conductive fibers” is used to describe thin, thread-like structures formed from or including a conductive material, which can vary in length and diameter, and can be natural or synthetic.

As described herein, the term “conductive filaments” is used to describe thin and thread-like structures formed from conductive material, but that are typically longer and continuous relative to conductive fibers, and are produced using various manufacturing processes, including extrusion and spinning.

As described herein, the term “conductive tows” is used to describe a bundle of conductive filaments or conductive fibers that are twisted or bound together such that the individual filaments or fibers in the tow are typically not separated, and the tow is used as a single unit.

As utilized herein, the terms “substantially’ and similar terms are intended to have a broad meaning in harmony with the common and accepted usage by those of ordinary skill in the art to which the subject matter of this disclosure pertains. For example, the term “substantially flat” would mean that there may be de minimis amount of surface variations or undulations present due to manufacturing variations present on an otherwise flat surface. It should be understood by those of skill in the art who review this disclosure that these terms are intended to allow a description of certain features described and claimed without restricting the scope of these features to the precise arrangements and/or numerical ranges provided. Accordingly, these terms should be interpreted as indicating that insubstantial or inconsequential modifications or alterations of the subject matter described and claimed are considered to be within the scope of the inventions as recited in the appended claims.

As described herein, the term “operating temperature” refers to the temperature of conductor layers included in the apparatus which conduct the electric current. In some embodiments, the operating temperature may be different from ambient temperature which refers to temperature of the environment in which the apparatus described herein is located. For example, in some embodiments, the ambient temperature can be in a range of −60 degrees Celsius (e.g., extreme cold climates such as arctic region) to 55 degrees Celsius (e.g., extreme hot climates such as desert region) and the operating temperature may be in a range of −40 degrees Celsius to 250 degrees Celsius. In some embodiments, the operating temperature is higher than the ambient temperature.

In some embodiments, the apparatus described herein may include a coating or a layer disposed on the apparatus that provides cooling to the apparatus. In some embodiments, the operating temperature may be substantially similar to the ambient temperature, or the operating may be lower than the ambient temperature.

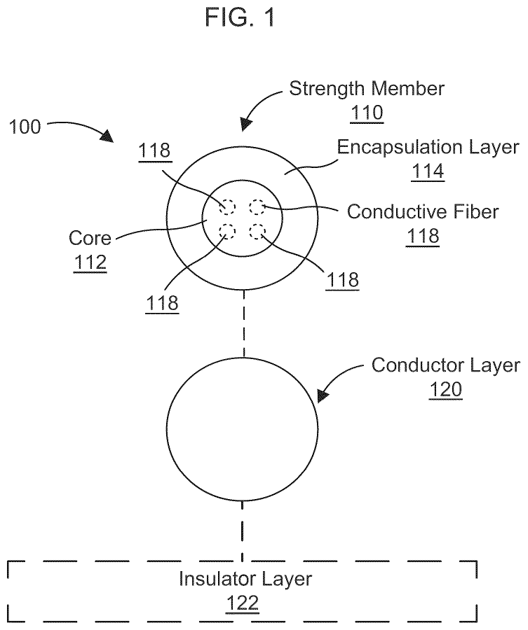

FIG. 1 is a schematic illustration of a conductor 100, according to an embodiment. The conductor 100 includes a strength member 110, a conductor layer 120 disposed around the strength member 110, and optionally, an insulator layer 122 disposed on the conductor layer 120. The strength member 110 includes a core 112 formed from a composite material, and an encapsulation layer 114 disposed around the core 112, as described in further detail herein.

The strength member 110 includes the core 112 and, the encapsulation layer 114 disposed around the core 112, for example, disposed circumferentially around the core 112. In some embodiments, a conductor layer 120 is disposed on the encapsulation layer 114.

The core 112 may be formed from a composite material. In some embodiments, the core 112 may include fibers (e.g., reinforcement fibers such as carbon fibers, glass fibers, quartz, ceramic fibers) dispersed within a continuous or discontinuous polymeric matrix. In some embodiments, the core 112 may include fibers (e.g., reinforcement fibers such as carbon fibers, glass fibers, quartz, ceramic fibers) disposed within a continuous or discontinuous polymeric matrix. In some embodiments, the core 112 may include reinforcement materials e.g., nano-size or micro-size materials dispersed within a continuous or discontinuous polymeric matrix. In some embodiments, the core 112 may further include fillers or additives (e.g., nanoadditives).

In some embodiments, the composite material may include nonmetallic fiber reinforced metal matrix composite, carbon fiber reinforced composite of either thermoplastic or thermoset matrix or even metallic matrix, or composites reinforced with other types of fibers such as quartz, AR-Glass, E-Glass, S-Glass, H-Glass, silicon carbide, silicon nitride, alumina, basalt fibers, specially formulated silica fibers, any other suitable composite material, or any combination thereof. In some embodiments, the composite material includes a carbon fiber reinforced composite of a thermoplastic or thermoset resin. The reinforcement in the composite strength member(s) can be discontinuous such as whiskers or chopped fibers, or continuous fibers in substantially aligned configurations (e.g., parallel to axial direction) or randomly dispersed (including helically wind or woven configurations). In some embodiments, the composite material may include a continuous or discontinuous polymeric matrix composite reinforced by carbon fibers, glass fibers, quartz, ceramic fibers such as alumina fibers, or other reinforcement materials, and may further include fillers or additives (e.g., nanoadditives). In some embodiments, the core 112 may include a carbon composite including a polymeric matrix of epoxy resin cured with anhydride hardeners.

In some embodiments, the core 112 may be electrically insulative. In some embodiments, the core 112 may be configured to be conductive. For example, in some embodiments, a plurality of conductive elements 118 are disposed in the core 112, for example, longitudinal conductive elements that extend along a longitudinal axis. Such conductive elements 118 may include, but are not limited to conductive fibers, conductive filaments, and/or conductive tows. For example, the plurality of conductive elements 118 may be embedded in the core 112, distributed uniformly (e.g., evenly distributed throughout a cross-section of the core 112), distributed randomly (e.g., distributed in the core 112 in no particular order) in the core 112, distributed in the core 112 in an asymmetric manner, mixed in with the composite material used to form the core 112, or are otherwise included in the core 112.

For example, in some embodiments, the plurality of conductive elements 118 may be distributed in the core 112 such that a higher concentration of the conductive elements 118 is present proximate to an outer surface of the core 112 relative to a concentration of the conductive elements proximate to a central axis of the core 112. In some embodiments, greater than 50% of a total amount of the plurality of conductive elements 118 may be located within less than 20% of a radial distance from the outer surface of the core 112 to the central axis of the core 112. In some embodiments, greater than 55% of a total amount of the plurality of conductive elements 118 may be located within less than 20% of a radial distance from the outer surface of the core 112 to the central axis of the core 112. In some embodiments, greater than 60% of a total amount of the plurality of conductive elements 118 may be located within less than 20% of a radial distance from the outer surface of the core 112 to the central axis of the core 112. In some embodiments, greater than 65% of a total amount of the plurality of conductive elements 118 may be located within less than 20% of a radial distance from the outer surface of the core 112 to the central axis of the core 112. In some embodiments, greater than 70% of a total amount of the plurality of conductive elements 118 may be located within less than 20% of a radial distance from the outer surface of the core 112 to the central axis of the core 112. In some embodiments, greater than 75% of a total amount of the plurality of conductive elements 118 may be located within less than 20% of a radial distance from the outer surface of the core 112 to the central axis of the core 112. In some embodiments, greater than 80% of a total amount of the plurality of conductive elements 118 may be located within less than 20% of a radial distance from the outer surface of the core 112 to the central axis of the core 112.

Having a larger number of conductive elements 118 located proximate to an outer surface of the core 112 may beneficially position a larger amount of conductive elements 118 at a location where a larger amount of electrical energy flows. For example, the conductor 100 may be included in an alternating current (AC) circuit and configured to transmit communicate or carry AC current. AC circuits often experience “skin effect” in which majority of the electrons being communicated through conductors preferably remain proximate to an outer surface of the conductor. Thus, when AC is communicated through each of the core 112 and the conductor layer 120 of the conductor, the majority of the electrons travel proximate to the outer surfaces of each of the conductor layer 120 and the core 112. In such implementations, it is advantageous to make the interface between the core 112 and a conductive layer positioned adjacent thereto, for example, the conductor layer 118, or the encapsulation layer 114 in embodiments in which an encapsulation layer 114 is included and is conductive. Distributing a higher percentage of the conductive elements 118 proximate to an outer surface of the core 112 provides a higher conductivity proximate to the outer surface of the core 112 where the skin effect is dominant. Since conductive elements 118 (e.g., CNT conductive fibers, filaments, or tows) can be expensive, distributing the conductive elements 118 at locations where the most benefit in terms of electrical energy transmission can be achieved reduces cost by distributing fewer conductive elements 118 proximate to the central axis of the core 112 where lesser electrons travel, thus providing higher conductivity at lowest cost.

The plurality of conductive elements 118 form a conductive network within the core 112 causing a substantial increase in the conductivity of the core 112. Thus, in addition to the conductor layer 120 being conductive, and optionally, the encapsulation layer 114 being conductive, the plurality of conductive elements 118 also cause the core to be conductive, thereby providing an additional conductive path for electrical energy through the conductor 100 or otherwise increase the overall conductivity of the conductor 100. In some embodiments, the plurality of conductive elements 118 may additionally serve as reinforcing members for mechanically reinforcing the core 112 and thereby, the conductor 100.

The conductive elements 118 may include at least one of conductive fibers, conductive filaments, or conductive tows. Any suitable conductive fiber, conductive filaments, or conductive tows 118 may be included in the core 112 including, but not limited to, conductive carbon nanotubes (CNTs) or graphene. For example, conductive CNTs that may be included or otherwise disposed in the core 112 in the form of fibers, filaments, and/or tows may include single walled CNTs, double walled CNTs, multiwalled CNTs, graphene coated CNTs, any other suitable CNTs, or any suitable combination thereof. In some embodiments, the conductive elements may include CNT tows having CNT fibers or CNT filaments in a range of about 10 CNT filaments to about 60,000 CNT filaments, inclusive in the tow (e.g., about 10, 20, 30, 40, 50, 100, 150, 200, 250, 300, 350, 400, 450, 500, 600, 700, 800, 900, or 1,000, 5,000, 10,000, 15,000, 20,000, 25,000, 30,000, 35,000, 40,000, 45,000, 50,000, 55,000, or about 60,000 filaments in the tow, inclusive of all ranges and values therebetween). In some embodiments, the CNTs may include GALVORN® 37 filament CNT fiber tow having a linear mass of about 10.7 mg/m, a linear resistance of about 18.0 ohm/meter, a specific conductivity of about 5,300 Sm²/kg, a break force of about 1.8 kg, and a tenacity of about 1,600 mN/tex. In some embodiments, the CNTs may include GALVORN® 199 filament CNT fiber tow having a linear mass of about 110 mg/m, a linear resistance of about 2.0 ohm/meter, a specific conductivity of about 4,500 Sm²/kg, a break force of about 10.0 kg, and a tenacity of about 900 mN/tex. In some embodiments, the conductive elements 118 may include conductive fibers, conductive filaments, or conductive tows formed from conductive polymers including, but not limited to, polyaniline (PANI), polypyrrole (PPy). polythiophene (PT), polyacetylene (PA), polyfluorene (PF), poly(3,4-ethylenedioxythiophene) (PEDOT), poly(3-hexylthiophene) (P3HT), polyphenylene vinylene (PPV), poly(3-methylthiophene) (PMT), polyindole (PIn), any other suitable conductive polymer or any suitable combination thereof.

In some embodiments, a quantity of the plurality of conductive elements 118 in the composite core 112 may be 100% (i.e., all the conductive elements used are highly conductive, for example, better than the conventional carbon fibers such as T700 fibers). The quantity of the plurality of conductive elements 118 could also be any ratio of mixture with the conventional nonconductive or less conductive reinforcement fibers, such as equal to or less than 50% by weight. In some embodiments, a quantity of the plurality of conductive elements 118 in the composite core 112 may be equal to or less than 10% by weight. In some embodiments, a quantity of the plurality of conductive elements 118 in the composite core 112 may be equal to or less than 1% by weight. In some embodiments, a quantity of the plurality of conductive elements 118 in the composite core 112 may be equal to or less than 0.8% by weight. In some embodiments, a quantity of the plurality of conductive elements 118 in the composite core 112 may be equal to or less than 0.6% by weight. In some embodiments, a quantity of the plurality of conductive elements 118 in the composite core 112 may be equal to or less than 0.5% by weight. In some embodiments, a quantity of the plurality of conductive elements 118 in the composite core 112 may be equal to or less than 0.4% by weight. In some embodiments, a quantity of the plurality of conductive elements 118 in the composite core 112 may be equal to or less than 0.3% by weight.

In some embodiments, a quantity of the plurality of conductive elements 118 in the composite core 112 is at most about 5.0% by weight. In some embodiments, a quantity of the plurality of conductive elements 118 in the composite core 112 is at most about 4.5% by weight. In some embodiments, a quantity of the plurality of conductive elements 118 in the composite core 112 is at most about 4.0% by weight. In some embodiments, a quantity of the plurality of conductive elements 118 in the composite core 112 is at most about 3.5% by weight. In some embodiments, a quantity of the plurality of conductive elements in the composite core 112 is at most about 3.0% by weight. In some embodiments, a quantity of the plurality of conductive elements 118 in the composite core 112 is at most about 2.5% by weight. In some embodiments, a quantity of the plurality of conductive elements 118 in the composite core 112 is at most about 2.0% by weight. In some embodiments, a quantity of the plurality of conductive elements 118 in the composite core 112 is at most about 1.5% by weight. In some embodiments, a quantity of the plurality of conductive elements 118 in the composite core 112 is at most about 1.0% by weight. In some embodiments, a quantity of the plurality of conductive elements 118 in the composite core 112 is at most about 0.5% by weight. In some embodiments, a quantity of the plurality of conductive elements 118 in the core 112 may be in a range of about 0.1% to about 1% by weight, inclusive (e.g., about 0.1%, 0.2%, 0.3, 0.4%, 0.5%, 0.6%, 0.7%, 0.8%, 0.9%, or about 1.0% by weight, inclusive).

In some embodiments, the conductive elements 118 include conductive filaments or conductive tows having a length in a range of about 10 microns to about 50 microns, inclusive (e.g., about 10, 15, 20, 25, 30, 35, 40, 45, or 50 microns, inclusive). In some embodiments, the conductive elements 118 include conductive filaments or conductive tows having a length of at least about 5 microns. In some embodiments, the conductive elements 118 include conductive filaments or conductive tows having a length of at least about 10 microns. In some embodiments, the conductive elements 118 include conductive filaments or conductive tows having a length of at least about 15 microns. In some embodiments, the conductive elements 118 include conductive filaments or conductive tows having a length of at least about 20 microns. In some embodiments, the conductive elements 118 include conductive filaments or conductive tows having a length of at least about 25 microns. In some embodiments, the conductive elements 118 include conductive filaments or conductive tows having a length of at least about 30 microns. In some embodiments, the conductive elements 118 include conductive filaments or conductive tows having a length of at least about 35 microns. In some embodiments, the conductive elements 118 include conductive filaments or conductive tows having a length of at least about 40 microns. In some embodiments, the conductive elements 118 include conductive filaments or conductive tows having a length of at least about 45 microns.

In some embodiments, the conductive elements 118 include conductive filaments or conductive tows having a length of at most about 50 microns. In some embodiments, the conductive elements 118 include conductive filaments or conductive tows having a length of at most about 45 microns. In some embodiments, the conductive elements 118 include conductive filaments or conductive tows having a length of at most about 40 microns. In some embodiments, the conductive elements 118 include conductive filaments or conductive tows having a length of at most about 35 microns. In some embodiments, the conductive elements 118 include conductive filaments or conductive tows having a length of at most about 30 microns.

In some embodiments, a conductivity of the plurality of conductive elements 118 may be in a range of about 10² S/m to about 10⁸ S/m, inclusive (e.g., about 10², 10³, 10⁴, 10⁵, 10⁶, 10⁷, or about 10⁸ S/m, inclusive of all ranges and values therebetween). In some embodiments, a conductivity of the plurality of conductive elements 118 may be at least about 10² S/m. In some embodiments, a conductivity of the plurality of conductive elements 118 may be at least about 10³ S/m. In some embodiments, a conductivity of the plurality of conductive elements 118 may be at least about 10⁴ S/m. In some embodiments, a conductivity of the plurality of conductive elements 118 may be at least about 10⁵ S/m. In some embodiments, a conductivity of the plurality of conductive elements 118 may be at least about 10⁶ S/m.

In some embodiments, a specific conductivity of the plurality of conductive elements 118 may be in a range of about 500 Sm²/kg to about 10,000 Sm²/kg, inclusive (e.g., about 500, 1,000, 1,500, 2,000, 2,500, 3,000, 3,500, 4,000, 4,500, 5,000, 5,500, 6,000, 6,500, 7,000, 7,500 8,000, 8,500 9,000, 9,500, or about 10,000 Sm²/kg, inclusive). In some embodiments, the specific conductivity of the plurality of conductive elements 118 may be at least 500 Sm²/kg. In some embodiments, the specific conductivity of the plurality of conductive elements 118 may be at least 1,000 Sm²/kg. In some embodiments, the specific conductivity of the plurality of conductive elements 118 may be at least 1,500 Sm²/kg. In some embodiments, the specific conductivity of the plurality of conductive elements 118 may be at least 2,000 Sm²/kg. In some embodiments, the specific conductivity of the plurality of conductive elements 118 may be at least 2,500 Sm²/kg. In some embodiments, the specific conductivity of the plurality of conductive elements 118 may be at least 3,000 Sm²/kg. In some embodiments, the specific conductivity of the plurality of conductive elements 118 may be at least 3,500 Sm²/kg. In some embodiments, the specific conductivity of the plurality of conductive elements 118 may be at least 4,000 Sm²/kg. In some embodiments, the specific conductivity of the plurality of conductive elements 118 may be at least 4,500 Sm²/kg. In some embodiments, the specific conductivity of the plurality of conductive elements 118 may be at least 5,000 Sm²/kg. In some embodiments, the specific conductivity of the plurality of conductive elements 118 may be at least 5,500 Sm²/kg. In some embodiments, the specific conductivity of the plurality of conductive elements 118 may be at least 6,000 Sm²/kg. In some embodiments, the specific conductivity of the plurality of conductive elements 118 may be at least 6,500 Sm²/kg. In some embodiments, the specific conductivity of the plurality of conductive elements 118 may be at least 7,000 Sm²/kg. In some embodiments, the specific conductivity of the plurality of conductive elements 118 may be at least 7,500 Sm²/kg. In some embodiments, the specific conductivity of the plurality of conductive elements 118 may be at least 8,000 Sm²/kg. In some embodiments, the specific conductivity of the plurality of conductive elements 118 may be at least 8,500 Sm²/kg. In some embodiments, the specific conductivity of the plurality of conductive elements 118 may be at least 9,000 Sm²/kg. In some embodiments, the specific conductivity of the plurality of conductive elements 118 may be at least 9,500 Sm²/kg. In some embodiments, the specific conductivity of the plurality of conductive elements 118 may be at least 10,000 Sm²/kg.

Inclusion of the conductive elements 118 in the core 112 advantageously cause the core 112 to be conductive such that the core 112 has a resistance that is equal to or less than 50% of a resistance of a comparable core that does not include the plurality of conductive elements 118. In some embodiments, the core 112 has a resistance that is equal to or less than 40% of a resistance of a comparable core that does not include the plurality of conductive elements 118. In some embodiments, the core 112 has a resistance that is equal to or less than 35% of a resistance of a comparable core that does not include the plurality of conductive elements 118. In some embodiments, the core 112 has a resistance that is equal to or less than 30% of a resistance of a comparable core that does not include the plurality of conductive elements 118. In some embodiments, the core 112 has a resistance that is equal to or less than 25% of a resistance of a comparable core that does not include the plurality of conductive elements 118. In some embodiments, the core 112 has a resistance that is equal to or less than 20% of a resistance of a comparable core that does not include the plurality of conductive elements 118.

In some embodiments, the core 112 may have a resistance of less than about 2 ohms. In some embodiments, the core 112 has a resistance that is at most 50% of a resistance of a comparable core that does not include the plurality of conductive elements 118 (e.g., a pure carbon core). In some embodiments, the core 112 has a resistance that is at most 45% of a resistance of a comparable core that does not include the plurality of conductive elements 118. In some embodiments, the core 112 has a resistance that is at most 40% of a resistance of a comparable core that does not include the plurality of conductive elements 118. In some embodiments, the core 112 has a resistance that is at most 35% of a resistance of a comparable core that does not include the plurality of conductive elements 118. In some embodiments, the core 112 has a resistance that is at most 30% of a resistance of a comparable core that does not include the plurality of conductive elements 118. In some embodiments, the core 112 has a resistance that is at most 25% of a resistance of a comparable core that does not include the plurality of conductive elements 118. In some embodiments, the core 112 has a resistance that is at most 20% of a resistance of a comparable core that does not include the plurality of conductive elements 118. In some embodiments, the core 112 has a resistance that is in a range of about 20% to about 50%, inclusive (e.g., about 20%, 25%, 30%, 35%, 40%, 45%, or 50%, inclusive) of a resistance of a comparable core that does not include the plurality of conductive elements 118.

In some embodiments, a ratio of a resistivity of the core 112 including the plurality of conductive elements 118 to a resistivity of a core that does not include the plurality of conductive elements 118 is equal to or less than 1:2. In some embodiments, a ratio of a resistivity of the core 112 with the plurality of conductive elements 118 to a resistivity of a core that does not include the plurality of conductive elements 118 is equal to or less than 0.9:2. In some embodiments, a ratio of a resistivity of the core 112 with the plurality of conductive elements 118 to a resistivity of a core that does not include the plurality of conductive elements 118 is equal to or less than 0.8:2. In some embodiments, a ratio of a resistivity of the core 112 with the plurality of conductive elements 118 to a resistivity of a core that does not include the plurality of conductive elements 118 is equal to or less than 0.7:2. In some embodiments, a ratio of a resistivity of the core 112 with the plurality of conductive elements 118 to a resistivity of a core that does not include the plurality of conductive elements 118 is equal to or less than 0.6:2. In some embodiments, a ratio of a resistivity of the core 112 with the plurality of conductive elements 118 to a resistivity of a core that does not include the plurality of conductive elements 118 is equal to or less than 0.5:2. In some embodiments, a ratio of a resistivity of the core 112 with the plurality of conductive elements 118 to a resistivity of a core that does not include the plurality of conductive elements 118 is equal to or less than 0.4:2. In some embodiments, a ratio of a resistivity of the core 112 with the plurality of conductive elements 118 to a resistivity of a core that does not include the plurality of conductive elements 118 is equal to or less than 0.3:2. In some embodiments, a ratio of a resistivity of the core 112 with the plurality of conductive elements 118 to a resistivity of a core that does not include the plurality of conductive elements 118 is equal to or less than 0.2:2. In some embodiments, a ratio of a resistivity of the core 112 with the plurality of conductive elements 118 to a resistivity of a core that does not include the plurality of conductive elements 118 is equal to or less than 0.1:2. In some embodiments, a ratio of a resistivity of the core 112 with the plurality of conductive elements 118 to resistance of a comparable core that does not include the plurality of conductive elements 118 is in a range of about 0.1:2 to about 1:2, inclusive.

In some embodiments, in addition to the conductive elements 118 being included in the core 112, conductive fillers or conductive additives may be included in the composite matrix (e.g., resin matrix) that forms a bulk volume of the core 112. Inclusion of such conductive fillers in the resin matrix itself can beneficially make the composite matrix conductive, thus providing an additional conductive path through the core 112 in addition to the conductive pat provided by the conductive elements 118. The additional path provided by the conductive fillers or additives may provide a separate conductive path through the composite matrix itself or provide a synergistic conductive path along with the conductive elements 118 that extend through the composite matrix forming the core 112. Suitable conductive fillers or conductive additives that may be included in the composite matrix to be part of the composite matrix can include, but are not limited to carbon black particles, graphene particles, CNTs, silver nanoparticles, copper nanoparticles, gold particles, aluminum particles, nickel particles, zinc particles, iron oxide particles, indium tin oxide (ITO) particles, any other suitable conductive particles or any suitable combination thereof.

The core 112 may have any suitable cross-sectional width (e.g., diameter). In some embodiments, the core 112 has a diameter in a range of about 2 mm to about 15 mm, inclusive (e.g., 2, 3, 4, 5, 6, 7, 8, 9, 10, 11, 12, 13, 14, or 15 mm, inclusive). In some embodiments, the core 112 may have a diameter in a range of about 3.5 mm to about 10 mm, inclusive. In some embodiments, the core 112 may have a diameter in a range of about 10 mm to about 15 mm, inclusive. In some embodiments, the core 112 may have a diameter in a range of about 7 mm to about 12 mm, inclusive. In some embodiments, the core 112 may have a diameter of about 9 mm. In some embodiments, the core 112 may have a diameter in a range of about 2 mm to about 5 mm, inclusive. In some embodiments, the core 112 may have a diameter of about 3.5 mm.

In some embodiments, the core 112 may have a glass transition temperature (e.g., for thermoset composites), or melting point of at least about 70 degrees Celsius (e.g., at least 75, at least 80, at least 90, at least 100, at least 120, at least 140, at least 150, at least 160, at least 180, at least 200, at least 220, at least 240, or at least 250, degrees Celsius, inclusive). The glass transition temperature or melting point of the core 112 may correspond to a threshold operating temperature of the conductor 100, which may limit the ampacity of the conductor 100. In other words, a maximum amount of current that can be delivered through the conductor 100 is the current at which the operating temperature of the conductor 100, or at least the temperature of the core 112 is less than the glass transition temperature or melting point of the composite core 112.

In some embodiments, the core 112 defines a circular cross-section. In some embodiments, the core 112 may define an ovoid, elliptical, polygonal, or asymmetrical cross-section. In some embodiments, the strength member 110 may include a single core 112. In other embodiments, the strength member 110 may include multiple cores, for example, 2, 3, 4, or even more, with the encapsulation layer 114 being disposed around the multiple cores or around each individual core. In such embodiments, each of the multiple cores may be substantially similar to each other, or at least one of the multiple cores may be different from the other cores (e.g., have a different size, different shape, formed from a different material, have components embedded therein, etc.).

In some embodiments, the core 112 is solid, i.e., does not include any holes or voids therein other than a de minimis amount of naturally occurring voids or porosities that may form during a fabrication process of the core 112. In some embodiments, the core 112 may be hollow, for example, define one or more deliberately formed channels or voids therein or therethrough (e.g., extending axially along and/or defined about a longitudinal axis of the strength member 110). Sensing or transmission components may be embedded within the void or channels defined in the core 112. For example, in some embodiments, sensors such as strain gages, accelerometers, or optical fiber sensors may be disposed within, or extend through the core 112. The sensors may be configured to sense various operating parameters of the conductor 100, for example, mechanical strain, sag (i.e., the vertical difference between the points of support of the conductor 100 to the lowest point of the conductor 100), operating temperature, voltage, or current passing through the conductor 100, any other suitable operating parameter or a combination thereof. In some embodiments, the optical fibers extending through the core 112 may include communication optical fibers. In such embodiments, the optical fibers may communicate an optical signal (e.g., transmit sensor data, internet, or media signals, etc.) therethrough.

In some embodiments, the encapsulation layer 114 may be disposed around the core 112, for example, circumferentially around the core 112. In some embodiments, an insulation layer (not shown) may optionally be interposed between the core 112 and the encapsulation layer 114. The insulation layer may be formed from any suitable insulative material, for example, glass fibers (disposed either substantially parallel to axial direction or woven or braided glass), a resin layer, an insulative coating, any other suitable insulative material or a combination thereof. In some embodiments, the insulation layer may also be disposed on axial ends of the core 112, for example, to protect the axial ends of the core 112 from corrosive chemicals, environmental damage, etc.

The encapsulation layer 114 may be formed from any suitable electrically conductive or non-conductive material. In some embodiments, the encapsulation layer 114 may be formed from a conductive material including, but not limited to aluminum (e.g., 1350-H19), annealed aluminum (e.g., 1350-0), aluminum alloys (e.g., Al—Zr alloys, 6000 series Al alloys such as 6201-TSl, -T82,-T83, 7000 series Al alloys, 8000 series Al alloys, etc.), copper, copper alloys (e.g., copper magnesium alloys, copper tin alloys, copper micro-alloys, etc.), any other suitable conductive material, or any combination thereof. In some embodiments, the encapsulation layer 114 is formed from Al and is optionally pretensioned, i.e., is under tensile stress after being disposed on the core 112. In some embodiments, the encapsulation layer 114 includes aluminum. In some embodiments, the encapsulation layer 114 may be formed from a non-conductive material, for example, polymers, plastics, rubber, silicone, etc.

The encapsulation layer 114 may be disposed on the core 112 using any suitable process. In some embodiments, the encapsulation layer 114 may be disposed around the core 112 using a conforming machine. For example, the encapsulation process may be performed with a similarly functional machine other than a conforming machine and be optionally further drawn to achieve target characteristics of the encapsulation layer 114 (e.g., a desired geometry or stress state). The conforming machines or the similar machines used for disposing the encapsulation layer 114 may allow quenching of the encapsulation layer 114. The conforming machine may be integrated with stranding machine, or with pultrusion machines used in making fiber reinforced composite strength members. While FIG. 1 shows a single encapsulation layer 114 disposed around the core 112, in some embodiments, multiple encapsulation layers 114 may be disposed around the core 112. In such embodiments, each of the multiple encapsulation layers 114 may be substantially similar to each other, or may be different from each other (e.g., formed from different materials, have different thicknesses, have different tensile strengths, etc.). In some embodiments, the core 112 may include a carbon fiber reinforced composite, and the encapsulation layer 114 may include aluminum, for example, pretensioned or precompressed aluminum. While a single core 112 is shown in FIG. 1, in some embodiments, the conductor 100 may include a plurality of cores 112, each of which may include the plurality of conductive elements 118, and each having one or more encapsulation layers 114 disposed thereon. In some embodiments, the encapsulation layer 114 may also include a semiconductor material, or a semiconductor material alloy, for example, any of the semiconductor materials as described with respect to the conductor layer 120.

In some embodiments, the interface between the core 112 and the encapsulation layer 114 may optionally include surface features, for example, grooves, slots, notches, indents, detents, etc. to enhance adhesion, bonding and/or interfacial locking between a radially outer surface of the core 112 and a radially inner surface of the encapsulation layer 114. Such surface features may facilitate retention and preservation of the stress from pretensioning in the encapsulation layer 114. In some embodiments, the composite core 112 may have a glass fiber tow disposed around its outer surface to create a screw shape or twisted surface. In some embodiments, a braided or woven fiber layer is applied in the outer layer of the core 112 to promote interlocking or bonding between the core 112 and the encapsulation layer 114.

In some embodiments, the encapsulation layer 114 may have a thickness in a range of about 0.1 mm to about 5 mm, inclusive, or even higher (e.g., 0.1, 0.2, 0.5, 1, 1.5, 2.0, 2.5, 3.0, 3.5, 4.0, 4.5, 5.0 mm, inclusive, or even higher). In some embodiments, a ratio of an outer diameter of the encapsulation layer 114 to an outer diameter of the core 112 is in range of about 1.2:1 to about 5:1, inclusive (e.g., 1.2:1, 1.5:1, 2:1, 2.5:1, 3:1, 3.5:1, 4:1, 4.5:1, or 5:1, inclusive).

In some embodiment, the strength member 110 may have a minimum level of tensile strength, for example, at least 600 MPa (e.g., at least 600, at least 700, at least 800, at least 1,000, at least 1,200, at least 1,400, at least 1,600, at least 1,800, or at least 2,000 MPa). In some embodiments, the elongation during pretension of the strength member 110 may include elongation by at least 0.001% strain (e.g., at least 0.001%, at least 0.01%, at least 0.05%, at least 0.1%, at least 0.15%, at least 0.2%, at least 0.25%, at least 0.3%, at least 0.35%, at least 0.4%, at least 0.45%, or at least 0.5% strain, inclusive) depending on the type of strength members and the degree of knee point reduction, and the strength member 110 may be pre-tensioned before or after entering the conforming machine. Moreover, the strength member 110 may be configured to endure radial compression from crimping of conventional fittings as well as radial pressure during conforming of drawing down process or folding and molding of at least 3 kN (e.g., at least 3, at least 4, at least 5, at least 10, at least 15, at least 20, or at least 25 kN, inclusive), for example for composite cores 112 with little to substantially no plastic deformation.

In some embodiments, the encapsulation layer 114 may have an outer surface that is configured to be smooth and shiny (e.g., surface treated) so as to reduce absorptivity (i.e., enhance reflectivity) thus reducing an operating temperature of the core 112. Examples of encapsulation layers 114 having a shiny outer surface that may be included in the conductor 100 are described in detail in U.S. Pat. No. 11,854,721 (the “'721 patent”), filed Mar. 24, 2023, and entitled “Composite Conductors Including Radiative and/or Hard Coatings and Methods of Manufacture Thereof,” the entire disclosure of which is incorporated herein by reference.

In some embodiments, the outer surface of the encapsulation layer 114 may be surface treated (e.g., plasma treated, texturized, etc.) to have the absorptivity or reflectivity as described above. In some embodiments, the strength member 110, i.e., the outer surface of the encapsulation layer 114 may be optionally coated with an inner coating (not shown) to reduce solar absorptivity. For example, the inner coating (not shown) may be disposed between the encapsulation layer 114 and the conductor layer 120. Examples of such inner coatings are described in detail in the '721 patent.

A conductor layer 120 is disposed around the strength member 110 and configured to transmit electrical signals therethrough. The conductor layer 120 includes a low resistance material (e.g., a superconductor material). Specifically, the conductor layer 120 includes a low resistance material that has a resistivity of less than 10⁻¹⁰ Ω·cm over an operating temperature in a range of from about −40 degrees Celsius to about 250 degrees Celsius.

In some embodiments, the low resistance material includes a superconductor or superconductor like material. In some embodiments, the low resistance material includes a chiral superconductor material. Without being bound by a theory, chiral superconductors are a class of unconventional superconductors that spontaneously break time-reversal symmetry and exhibit Cooper pairing with non-zero angular momentum. Chiral superconductor materials may exhibit magnetic hysteresis, anomalous Hall effects, and orbital magnetism, even in the absence of an external magnetic field.

In some embodiments, the chiral superconductor material includes rhombohedral stacked multilayer graphene, such as tetra-layer or penta-layer graphene, which exhibits gate-tunable flat bands and strong electron correlation effects. In some embodiments, the chiral superconductor materials may exhibit superconductivity at temperatures up to about 300 mK. In some embodiments, the chiral superconductor materials may exhibit critical magnetic field (BL) up to 1.4 T. In some embodiments, the low resistance material can include a superconductor material showing a chiral superconducting state that emerges from a spin- and valley-polarized quarter-metal phase, potentially exhibiting domain-dependent hysteresis consistent with broken time-reversal symmetry.

In some embodiments, the chiral superconductor material can include a material that supports a complex-valued chiral order parameter, such as p+ip pairing symmetry, and may host topologically nontrivial states including localized Majorana modes and chiral edge states. In some embodiments, the chiral superconducting material may be configured to operate under ambient or elevated pressure and may be incorporated into the conductor layer 120 or as a component of a multilayer conductor structure.

In some embodiments, the conductor layer 120 includes a chiral superconductor material having a coherence length close to inter-electron distance (e.g., average spacing between conduction electrons), indicating strong coupling and proximity to the Bardeen-Cooper-Schrieffer (BCS)-Bose-Einstein Condensate (BEC) crossover regime. In some embodiments, the chiral superconductor material may be disposed in a pressurized or encapsulated configuration to maintain superconducting properties under operating conditions.

In some embodiments, the inclusion of chiral superconductor materials in the conductor layer 120 may enable advanced functionalities beyond conventional low-resistance transmission. For example, chiral superconductors may support dissipationless edge currents and exhibit topologically protected transport properties, which may be advantageous for grid-level fault tolerance, signal integrity, and energy efficiency. In some embodiments, the chiral superconducting state may be leveraged for real-time sensing or switching applications, wherein domain-wall dynamics or magnetic hysteresis effects are used to detect or respond to changes in current, voltage, or environmental conditions. Such features may be particularly beneficial in smart grid architectures, distributed energy systems, or quantum-enhanced power distribution networks.

In some embodiments, the low resistance material may include ceramic-based high-temperature superconductors, such as copper-doped lead apatite compounds (e.g., Pb₁₀₋ₓCuₓ(PO₄)₆), which have been reported in the art to exhibit superconductivity at or near ambient pressure and/or temperature. These materials offer promising characteristics for grid-level applications and may be incorporated into the conductor layer 120 to achieve ultra-low resistivity across a wide operating temperature range. In some embodiments, the conductor layer may 120 may include a mixture, alloy, and/or composite of a low resistance material and a metallic material, for example, a mixture of chiral superconductor material or ceramic based high temperature material as described herein, and aluminum or aluminum alloys, steel or steel alloys, copper or copper alloy, or any other metallic material, or any suitable combination thereof.

In some embodiments, the conductor layer 120 includes a low resistance material that has a resistivity of less than 10⁻¹⁰ Ω·cm over at least a portion of an operating temperature in a range of 30 degrees Celsius to 200 degrees Celsius, inclusive. Having a conductor layer 120 that includes a low resistance material, for example, a superconductor or superconductor like material allows the conductor 100 to have substantially no loss in electrical energy transmission and, substantially low heat generation, thus allowing low temperature operation of the conductor 100. As described in further detail herein, the composite core 112 of the conductor 100 may have a glass transition temperature, which is the temperature above which a polymer or composite material undergoes transition from rigid and glassy to rubbery and flexible due to initiation of molecular mobility in the polymer or composite matrix or melting temperature which is in a range of 60 degrees Celsius to 250 degrees Celsius. Having a low resistance material included in the conductor layer 120 may allow the conductor 100 and thereby, the core 112 to operate at a temperature that is substantially below the glass transition or melting temperature of the core 112, thus maintaining the physical integrity of the core 112 and thereby, the low sag and high tensile strength properties of the strength member 110. Moreover, low resistance operation inhibits electrical energy loss in the form of heat as the electrical energy flows through the conductor layer 120. This allows a larger amount of electrical energy to be transmitted through the conductor layer 120, thus significantly increasing its ampacity while reducing heat generation that can damage the composite material forming the core 112 of the strength member 110.

As previously described, the low resistance material has the low resistivity of less than 10⁻¹⁰ Ω·cm at an operating temperature (i.e., the operating temperature of the conductor layer 120) in a range of from about −40 degrees Celsius to about 250 degrees Celsius. In some embodiments, the operating temperature is in a range of −30 degrees Celsius to 240 degrees Celsius, −20 degrees Celsius to 230 degrees Celsius, −10 degrees Celsius to 220 degrees Celsius, 0 degrees Celsius to 210 degrees Celsius, 10 degrees Celsius to 200 degrees Celsius, 20 degrees Celsius to 190 degrees Celsius, 30 degrees Celsius to 180 degrees Celsius, 30 degrees Celsius to 170 degrees Celsius, 30 degrees Celsius to 160 degrees Celsius, 30 degrees Celsius to 150 degrees Celsius, 30 degrees Celsius to 140 degrees Celsius, 30 degrees Celsius to 120 degrees Celsius, 30 degrees Celsius to 110 degrees Celsius, 30 degrees Celsius to 100 degrees Celsius, 30 degrees Celsius to 90 degrees Celsius, 30 degrees Celsius to 80 degrees Celsius, 30 degrees Celsius to 70 degrees Celsius, or 30 degrees Celsius to 60 degrees Celsius

In some embodiments, the low resistance material has a porosity of about 0% to about 30% (e.g., about 27.9%). In some embodiment, the low resistance material may have a porosity in a range of about 25% to about 99%. In some embodiments, the low resistance material has a porosity in a range of about 0.001% to about 25%. In some embodiments, the low resistance material has a porosity in a range of about 0.1% to about 20%. In some embodiments, the low resistance material has a porosity in a range of about 50% to about 98%). In some embodiments, the low resistance material has a porosity in a range of about 90% to about95%. The porosities may be determined by porosimeter (e.g., a mercury intrusion porosimeter) or any other suitable porosity measurement apparatus.

In some embodiments, the low resistance material is not brittle such that the low resistance material can be formed into a shape of a coil, a tape, a wire, or strand wires that can be disposed, for example, via conforming or extruding on the strength member 110 to form the conductor layer 120.

In some embodiments, the low resistance material includes a superconductor or a superconductor like material.

In some embodiments, the superconductor or superconductor like material may have a critical temperature (T_{c}) in a range of about 25 degrees Celsius to about 250 degrees Celsius, inclusive (e.g., about 25° C., about 30° C., about 35° C., about 40° C., about 45° C., about 50° C., about 55° C., about 60° C., about 70° C., about 75° C., about 80° C., about 85° C., about 90° C., about 95° C., about 100° C., about 105° C., about 110° C., about 115° C., about 120° C., about 125° C., about 130° C., about 135° C., about 140° C., about 145° C., about 150° C., about 155° C., about 160° C., about 165° C., about 170° C., about 175° C., about 180° C., about 185° C., about 190° C., about 195° C., about 200° C., about 205° C., about 210° C., about 215° C., about 220° C., about 225° C., about 230° C., about 235° C., about 245° C., or about 250° C., inclusive) under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the superconductor or superconductor like material may have a critical temperature (T_{c}) in a range of about 30 degrees Celsius to about 250 degrees Celsius, inclusive under an ambient pressure. In some embodiments, the superconductor or superconductor like material may have a critical temperature (T_{c}) in a range of about 30 degrees Celsius to about 250 degrees Celsius, inclusive, under a pressure of less than about 20 GPa.

In some embodiments, the superconductor or superconductor like material may have a critical temperature (T_{c}) of about 25° C. or greater, about 30° C. or greater, about 35° C. or greater, about 40° C. or greater, about 45° C. or greater, about 50° C. or greater, about 55° C. or greater, about 60° C. or greater, about 65° C. or greater, about 70° C. or greater, about 75° C. or greater, about 80° C. or greater, about 85° C. or greater, about 90° C. or greater, about 95° C. or greater, about 100° C. or greater, about 105° C. or greater, about 115° C. or greater, about 120° C. or greater, about 125° C. or greater, about 130° C. or greater, about 135° C. or greater, about 140° C. or greater, about 145° C. or greater, about 150° C. or greater, about 155° C. or greater, about 160° C. or greater, about 165° C. or greater, about 170° C. or greater, about 175° C. or greater, about 180° C. or greater, about 185° C. or greater, about 190° C. or greater, about 195° C. or greater, about 200° C. or greater, about 205° C. or greater, about 210° C. or greater, about 215° C. or greater, about 220° C. or greater, about 225° C. or greater, about 230° C. or greater, about 235° C. or greater, about 200° C. or greater, about 205° C. or greater, about 210° C. or greater, about 215° C. or greater, about 220° C. or greater, about 225° C. or greater, about 230° C. or greater, about 235° C. or greater, about 240° C. or greater, about 245° C. or greater, or about 250° C. or greater under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the critical temperature of the superconductor or superconductor like material is about 30 degrees Celsius or greater under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the critical temperature of the superconductor or superconductor like material is about 50 degrees Celsius or greater under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the critical temperature of the superconductor or superconductor like material is about 80 degrees Celsius or greater under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the critical temperature of the superconductor or superconductor like material is about 120 degrees Celsius or greater under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the critical temperature of the superconductor or superconductor like material is about 150 degrees Celsius or greater under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the critical temperature of the superconductor or superconductor like material is about 170 degrees Celsius or greater under a pressure of less than about 20 GPa, less than about 15 GPa, less than about 10 GPa, less than about 5 GPa, less than about 2 GPa, less than about 1 GPa, less than about 500 MPa, less than about 250 MPa, less than about 150 MPa, less than about 100 MPa, less than about 10 MPa, less than about 1 MPa, less than about 500 kPa, less than about 300 kPa, less than about 200 kPa, or at an ambient pressure (i.e., 101.3 kPa).

In some embodiments, the conductor layer 120 may include a superconductor material having a critical magnetic field of 5 tesla (T) or over, 10 T or over, 20 T or over, 30 T or over, 40 T or over, 50 T or over, 60 T or over, 70 T or over, 80 T or over, 90 T or over, 100 T or over, 150 T or over, 200 T or over, 250 T or over, 300 T or over, 350 T or over, 400 T or over, 450 T or over, or 500 T or over.

In some embodiments, the superconductor or superconductor like material included in the conductor layer 120 includes a ceramic compound. In some embodiments, the superconductor or superconductor like material includes at least one of metallic or intermetallic compound.

In some embodiments, the superconductor or superconductor like material includes a compound of Formula I,

$${A}_{a} {{B}_{b} ( {E O}_{4} )}_{c} {X}_{d} \qquad Formula I$$

or a salt, hydrate, solvate, enantiomer, stereoisomer, or tautomer thereof, wherein A is Ca, Ba, Sr, Sn, Pb, Y, La, Ce or combinations thereof; B is Cu, Cd, Zn, Mn, Fe, Ni, Ag or a combination thereof; E is P, As, V, Si, B, S or a combination thereof; X is F, Cl, OH, O, S, Se, Te or a combination thereof; each a and b is individually and independently selected from any number from 0 to 10; c is individually and independently selected from any number from 0 to 6; and d is individually and independently selected from any number from 0 to 4. In some embodiments, B may be substituted at the position of A in the crystal structure or may enter an empty space.

In some embodiments, the compound of formula I includes Pb₁₀₋ₓCuₓ(PO₄)₆O with x is between 0.9 and 1. In some embodiments, synthesis of Pb₁₀₋ₓCuₓ(PO₄)₆O includes reacting a lanarkite (Pb₂SO₅=PbO·PbSO₄)) with copper phosphide (Cu₃P).

In some embodiments, the superconductor material includes a compound of Formula II,

$${MX}_{n} or {X}_{n} M , \qquad Formula II$$

or salts thereof, wherein Mis at least one of sulfur(S), thorium (Th), protactinium (Pa), uranium (U), Neptunium (Np), plutonium (Pu), americium (Am), curium (Cm), berkelium (Bk), californium (Cf), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), titanium (Ti), vanadium (V), chromium (Cr), manganese (Mn), yttrium (Y), zirconium (Zr), niobium (Nb), molybdenum (Mo), hafnium (Hf), tantalum (Ta) tungsten (W), rhenium (Re) or their isotopes; X is at least one of hydrogen (H), fluorine (F), chlorine (CI), bromine (Br), iodine (I), oxygen (O), sulfur(S), selenium (Se), tellurium (Te), nitrogen (N), phosphorus (P), arsenic (As), antimony (Sb), carbon (C), silicon (Si), germanium (Ge), boron (B) and their isotopes; and n is selected from any number from 0.05 to 20. In some embodiments, the compound of formula II further includes a dopant selected from at least one of nitrogen or boron.

In some embodiments, the superconductor or superconductor like material includes at least one of a pure cuprate superconductor or a doped cuprate superconductor. In some embodiments, the cuprate superconductors may include copper oxide compounds doped with various elements.

In some embodiments, the superconductor material includes at least one of yttrium barium copper oxide or bismuth strontium calcium copper oxide.

In some embodiments, the conductor layer including the low resistance material (e.g., a superconductor or superconductor like material) may include tapes, wires, a coil, or strands that are wound or wrapped around the strength. In some embodiments, the conductor layer 120 may include a composite or an alloy that includes the low resistance material mixed with, alloyed with, or dispersed in a base metallic material (e.g., aluminum, copper, zinc, metal alloy, etc.). In some embodiments, the conductor layer 120 has a multilayer structure such that the conductor layer 120 includes a plurality of layers. In some embodiments, at least one layer of the conductive layer 120 includes a low resistance material (e.g., a superconductor or superconductor material). For example, the conductor layer 120 includes a plurality of layers disposed radially one top of each other, with at least one layer of the plurality of layers including the low resistance material. In some embodiments, the layer of the conductor layer 120 that includes the low resistance material includes an inner layer of the conductor layer 120. In some embodiments, one or more outer layers included in the conductor layer 120 are disposed around the inner layer and configured to exert a pressure on the inner layer, for example, any of the pressure ranges or values described herein, to cause the low resistance material to have the low resistivity as described herein. Pressurizing may cause conductive layer 120 to have higher pressures (e.g., more than about 20 GPa, more than about 15 GPa, more than about 10 GPa, more than about 5 GPa, more than about 2 GPa, more than about 1 GPa, more than about 500 MPa, more than about 250 MPa, more than about 150 MPa, more than about 100 MPa, more than about 10 MPa, more than about 1 MPa, more than about 500 kPa, more than about 300 kPa, or more than about 200 kPa) that may lead to decrease in resistivity of the conductor layer 120. Without wishing to be bound by any particular, pressurizing may cause an increase in the critical temperature T_{c} of a superconductor material that may be included in the conductor layer 120, and/or may cause decrease in an electron-phonon coupling constant, λ, of a metal, which may lead to decrease in resistivity. In some embodiments, the conductor layer 120 includes a pressurizing layer and the encapsulation layer 114 prevents damage of the core 112 from the pressure exerted by the pressurizing layer. For example, in some embodiments, the conductor layer 120 may include a plurality of layers, and one or more outer layers of the conductor layer 120 disposed around an inner layer can be configured to exert a pressure on the inner layer. In some embodiments, the conductor layer 120 may also serve as a pressurizing layer.

In some embodiments, the conductor layer 120 may further include a plurality of strands of a conductive material. For example, the conductor layer 120 may include a plurality of layers. In some embodiments, at least one layer of the conductive layer 120 may include a superconductor material and least one layer of the conductive layer 120 may include plurality of strands of a conductive material. In some embodiments, the plurality of strands of conductive material may include, for example, aluminum, aluminum alloy, copper or copper alloy including micro alloy as conductive media, etc. In some embodiments, the conductor layer 120 may include a plurality of strands of conductive material including the low resistance material disposed on the strength member 110, that may be disposed in single or multiple layers on the strength member 110. In some embodiments, the conductor layer (e.g., each of the strands forming the conductor layer 120) may be formed of only the low resistance material. In some embodiments, the conductor layer 120 (e.g., each of the strands forming the conductor layer 120) may include an alloy including any of the low resistance material described herein. For example, the conductor layer 120 may include an aluminum-superconductor alloy, copper-superconductor alloy, or any other alloy including the superconductor material or any other low resistance material described herein. As previously described herein, some low resistance materials may include ceramic materials that are brittle. Forming alloys that include the low resistance materials described herein may enable working (e.g., extruding, forming, etc.) of such alloys into strands, coils, wires, or any other suitable shape for disposing on the strength member 110 while substantially retaining the low resistance properties in the conductor layer 120.

The conductor layer 120 may have any suitable cross-sectional shape, for example, circular, triangular, trapezoidal, etc. In some embodiments, the conductor layer 120 may further include a stranded aluminum, or aluminum-superconductor alloy layer that may be round or trapezoidal. In some embodiments, the conductor layer 120 may further include Z shaped strands. In some embodiments, the conductor layer 120 may further include S shaped strands.

In some embodiments, the strength member 110 may be optionally tensioned while the conductor layer 120 disposed around the strength member 110 may be applied to cause the conductor 100 to form a cohesive conductive hybrid rod that is spoolable onto a conductor reel. In some embodiments, to facilitate conductor spooling onto a reel and conductor spring back at ease, the conductor 100 may be optionally configured to be non-round (e.g., elliptical) such that the shorter axis (in conductor 100) is subjected to bending around a spool (or a sheaves wheel during conductor installation) to facilitate a smaller bend or spool radius, while the strength members 110 may be configured to have a longer axis to facilitate spring back for installation. The overall conductor 100 may be round with non-round strength member 110 or multiple strength members 110 arranged to be non-round, and the spooling bending direction may be along the long axis of the strength member 110 to facilitate spring back while not overly subjecting the conductor layer 120 with additional compressive force from spooling bending.

To further facilitate spooling of the conductor layer 120 on the strength member 110, in some embodiments, the conductor layer 120 may include multiple segments, for example, strands or sets of strands or wires of conductive material (e.g., 2, 3, 4, etc.), and each segment bonded to strength member 110 while retaining compressive stress, and the segments rotates one full rotation or more along the conductor 100 length (equal to one full spool in a reel) to facilitate easy spooling. Thus, the conductor 100 may be configured to have negligible skin effect (i.e., conducting layer thickness is less than the skin depth required at AC circuit frequency), with the strength member 110 being under sufficient residual tensile stress, and the conductor layer 120 (e.g., each of the strands of the conductive material) being mostly free of tension or under compressive stress. In some embodiments, the strands of the conductive material may be formed from a conforming machine, for example, by extruding hot deformable (e.g., semi solid) conductive material (e.g., aluminum) from a mold. The strands can be molded to be round, trapezoidal, or any other desirable shape. In some embodiments, the extrusion mold or die may have a stranding lay ratio defined therein so that during the stranding operation of the conductive strands, no shaping may be needed (e.g., removing of sharp corners or edges of the conductive strands to avoid corona as is performed in conventional stranding operations). In some embodiments, the conductive media may be extruded out of the mold or die at an angle so as to form conductive strands that wrap around the strength member 110 at an angle, as described herein.

In some embodiments, for AC applications where skin effect is prominent, the conductor layer 120 may include a plurality of layers of conductive strands disposed concentrically around the strength member 110, with each layer being of finite thickness to maximize skin effect for lowest AC resistance at minimal conductor content. In some embodiments, the conductor layer 120 may be optionally stranded to facilitate conductor spooling around a reasonably sized spool and facilitate conductor stringing. Accordingly, the smooth outer surface and the compact configuration can effectively reduce the wind load and ice accumulation on the conductor 100, resulting in less sag from ice or wind related weather events.

It should be appreciated that, the conductor layer 120 may be under no substantial tension while the strength member 110 may be pre-stretched/tensioned. After the pre-tension in the strength member 110 is released, the conductor layer 120 may be subjected to compression, which may minimize the shrinking back of the strength member 110. The strength member 110 made with composite materials may have a strength above 80 ksi, and a modulus ranging from 5 msi to 40 msi, and a CTE of about 1×10⁻⁶/° C. to about 8×10⁻⁶/° C., inclusive.

In some embodiments, the low resistance material included in the conductor layer 120 may include a precompressed metal or a precompressed alloy. In some embodiments, the low resistance material may include a precompressed superconductor material. Prior to disposed around the strength member 110, the low resistance material may be compressed by using a suitable method available in the art, for example, by a high-pressure wire extrusion method.

In some embodiments, the conductor layer 120 has a multilayer structure such that the conductor layer includes at least one layer including a low resistance material. In some embodiments, the conductor layer 120 may include a cooling layer (not shown) that surrounds the at least one layer including the superconductor material. The cooling layer can aid dissipating heat that may be generated by the strength member 110, for example, in embodiments, in which the core 112 and/or the encapsulation layer 114. For example, a heat insulation layer may be disposed between the strength member 110 and the conductor layer 120.

In some embodiments, an outer surface of the conductor layer 120 (e.g., outer surface of the outermost conductive strands or an outer surface of each of the conductive strands) or the insulator layer is treated with features and/or include features to cause the outer surface to have a solar absorptivity of less than 0.6 (e.g., less than 0.55, less than 0.5, less than 0.45, less than 0.4, less than 0.35, less than 0.3, less than 0.25, less than 0.2, less than 0.15, or less than 0.1, inclusive). In some embodiments, the outer surface has a solar absorptivity of less than 0.55. In some embodiments, the outer surface of the conductor layer 120 may be treated or otherwise configured to have a reflectivity of less than 50% corresponding to an operating temperature of greater than 90 degrees Celsius.

The outer surface of the conductor layer 120 may be configured to have low absorptivity using any suitable treatment or process. In some embodiments, an outer coating may be disposed on the outer surface of the conductor layer 120 in addition to, or alternatively to the outer surface being treated of the conductor layer, as described herein. The outer coating may be formulated to have a solar absorptivity of less than 0.6 (e.g., less than 0.6, less than 0.55, less than 0.5, 1 less than 0.45, less than 0.40, less than 0.35, less than 0.30, less than 0.25, less than 0.20, less than 0.15, less than 0.1, inclusive or even lower) at a wavelength of less than 2.5 microns, and a radiative emissivity of greater than 0.5 (e.g., greater than 0.50, greater than 0.55, greater than 0.60, greater than 0.65, greater than 0.70, greater than 0.75, greater than 0.80, greater than 0.85, greater than 0.90, greater than 0.95, inclusive, or even higher) at a wavelength in a range of 2.5 microns to 15 microns, inclusive at an operating temperature in a range of 60 degrees Celsius to 250 degrees Celsius, inclusive. In some embodiments, the outer coating may have an erosion resistance that is at least 5% greater than an erosion resistance of aluminum or aluminum alloys. In some embodiments, the outer coating has a Vickers hardness of greater than 175 MPa. Various examples of conductor layers, surface features and surface treatment methods of the outer surface of the conductor layer 120, and of outer coatings that may be disposed on an outer surface of the conductor layer, which may be used as the conductor layer 120, or that may be included in the conductor layer 120 are described in detail in the '721 patent. The solar absorptivity and radiative emissivity of the outer surface of the conductor layer 120 may allow the low resistance material (e.g., a superconductor or superconductor like material) included in the conductor layer 120 to operate below its critical temperature, thus allowing the low resistance material to retain its low resistivity properties, as well as preventing a temperature of the core 112 from exceeding its glass transition temperature or melting point.

In some embodiments, the core 112 may include a plurality of conductor elements 118 disposed therein, for example, dispersed randomly or in a particular order I the core 112 matrix. By incorporating the plurality of conductive elements 118 in the composite core 112 of the conductor 100, the core 112 can also made conductive in addition to the conductor layer 120 and in some embodiments, the encapsulation layer 114. This provides an additional conductive path for electrical current to be transmitted to the conductor 100 relative to comparable conductors that have cores that do not include the plurality of conductive elements 118, that are non-conductive or insulative, or that have a resistance that is at least 1.5 times of the resistance of the material used to form the conductor layer 120 (e.g., 1.5× the resistance of aluminum or an aluminum alloy) causing the conductor 100 to have several advantages over such comparable conductors. For example, the conductor 100 having the strength member 110 with the conductive core 112 has greater conductivity, greater ampacity, and lesser line loss relative to comparable conductors that do not include a conductive core, without the weight increase and increased sag.

In some embodiments, an insulator layer 122 (e.g., a jacket) may be disposed around the conductor layer 120. The insulator layer 122 may be formed from any suitable electrically insulative material, for example, rubber, plastics, or polymers (e.g., polyethylene, PTFE, PEEK high density polyethylene, cross-linked high density polyethylene, etc.). The insulator layer 122 may be configured to electrically isolate or shield the conductor 100. In some embodiments, the insulator layer 122 may be excluded.

In some instances, the conductor 100 may generate a line loss saving of about $1.79/m ($0.55/ft per year) annually. For a 10,000 km circuit, replacing conventional ACSR conductor with the conductor 100 as described herein can provide a saving of greater $1.6 billion in 30 years. With reduced line loss in the system, the conductor 100 can reduce compensatory generation, and also reduce associated greenhouse gas emission by greater than 26 Million Megaton over 30 years.

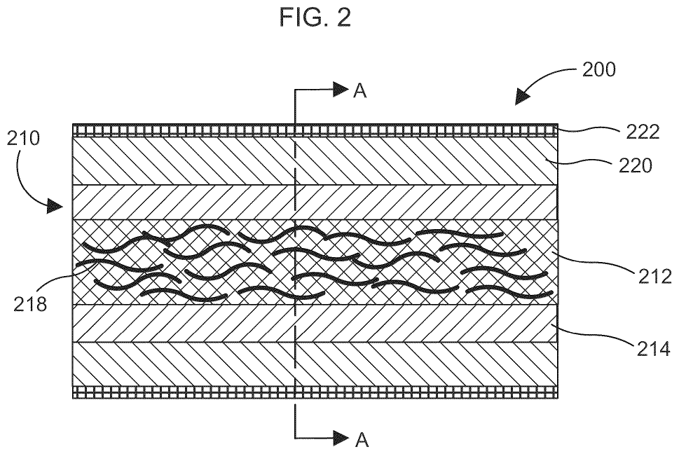

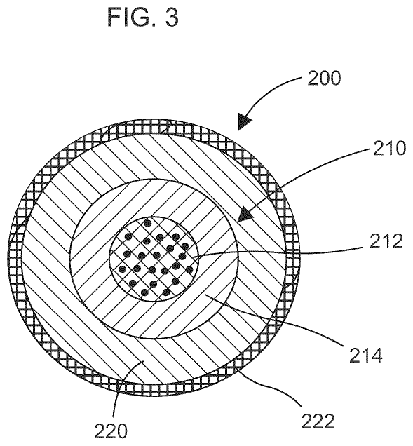

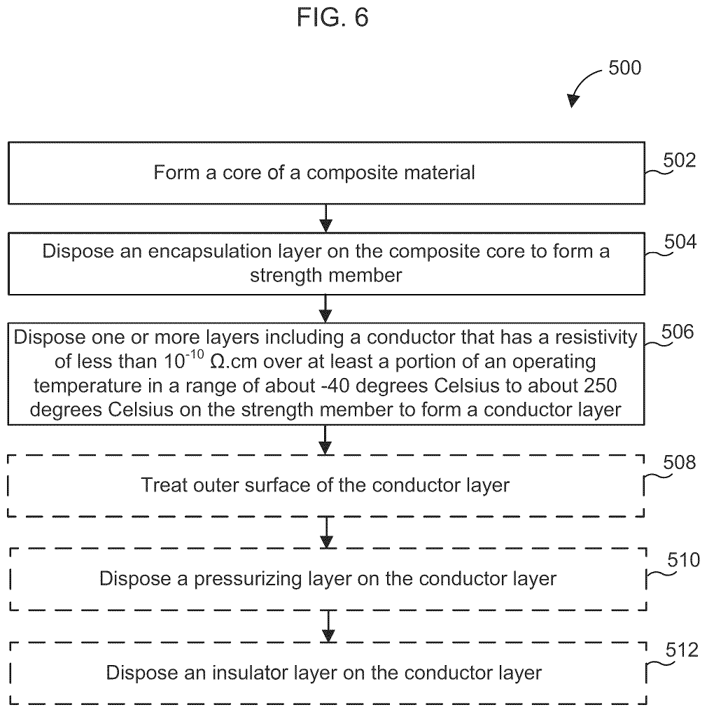

In some embodiments, the fabrication of the conductor 100 may be performed using method 500 illustrated in FIG. 6. FIG. 2 is a side cross-section view of a conductor 200, according to an embodiment, and FIG. 3 is a front cross-section view taken along the A-A in FIG. 2. The conductor 200 includes a strength member 210, a conductor layer 220 disposed around the strength member 210, and optionally, an insulator layer or jacket 222 disposed on the conductor layer 220.

The strength member 210 includes a core 212, for example, a composite core, and optionally, an encapsulation layer 214 disposed around the core 212, for example, disposed circumferentially around the core 212. The core 212 may be formed from any material, for example, a composite material as described with respect to the core 112 and therefore, not described in further detail herein.

In some embodiments, a plurality of conductive elements 218 may be disposed in the core 212, for example, longitudinal conductive elements that extend along a longitudinal axis. Such conductive elements 118 may include, but are not limited to conductive fibers, conductive filaments, and/or conductive tows. For example, the plurality of conductive elements 218 may be embedded in the core 212, distributed uniformly (e.g., evenly distributed throughout a cross-section of the core 212), distributed randomly (e.g., distributed in the core 212 in no particular order) within the core 212, distributed asymmetrically through the core 212, mixed in with the composite material used to form the core 212, or are otherwise included in the core 212. For example, in some embodiments, the plurality of conductive elements 218 may be distributed in the core 212 such that a higher concentration of the conductive elements 218 is present proximate to an outer surface of the core 212 relative to a concentration of the conductive elements 218 proximate to a central axis of the core 212. In some embodiments, greater than 50% of a total amount of the plurality of conductive elements 218 may be located within less than 20% of a radial distance from the outer surface of the core 212 to a center portion of the core 212, for example, as described in detail with respect to the conductive elements 118 included in the core 112.

The conductive elements 218 may include at least one of conductive fibers, conductive filaments, or conductive tows. Any suitable conductive fibers, conductive filaments, or conductive tows may be included in the core 212 including, but not limited to, conductive carbon nanotubes (CNTs) or graphene. For example, conductive CNTs that may be included or otherwise disposed in the core 112 may include single walled CNTs, double walled CNTs, multiwalled CNTs, graphene coated CNTs, any other suitable CNTs, any suitable combination thereof, or any other CNTs having any suitable electrical or structural properties as described in detail with respect to the conductive elements 118 of the conductor 100. In some embodiments, the conductive elements 218 may include CNT tows having CNT fibers or CNT filaments in a range of about 10 CNT filaments to about 60,000 CNT filaments, inclusive in the tow (e.g., about 10, 20, 30, 40, 50, 100, 150, 200, 250, 300, 350, 400, 450, 500, 600, 700, 800, 900, or 1,000, 5,000, 10,000, 15,000, 20,000, 25,000, 30,000, 35,000, 40,000, 45,000, 50,000, 55,000, or about 60,000 filaments in the tow, inclusive of all ranges and values therebetween). In some embodiments, the conductive elements 118 may include conductive fibers, conductive filaments, or conductive tows formed from conductive polymers including, but not limited to, polyaniline (PANI), polypyrrole (PPy), polythiophene (PT), polyacetylene (PA), polyfluorene (PF), poly(3,4-ethylenedioxythiophene) (PEDOT), poly(3-hexylthiophene) (P3HT), polyphenylene vinylene (PPV), poly(3-methylthiophene) (PMT), polyindole (PIn), any other suitable conductive polymer or any suitable combination thereof.

In some embodiments, a quantity of the plurality of conductive elements 218 in the composite core 212 may be 100% by weight. The quantity of the plurality of conductive elements 218 could also be any ratio of mixture with the conventional nonconductive or less conductive reinforcement fibers, such as equal to or less than 50% by weight. In some embodiments, a quantity of the plurality of conductive elements 218 in the composite core 212 may be equal to or less than 10% by weight. In some embodiments, a quantity of the plurality of conductive elements 218 in the composite core 212 may be equal to or less than 1% by weight. In some embodiments, a quantity of the plurality of conductive elements 218 in the composite core 212 may be equal to or less than 0.8% by weight. In some embodiments, a quantity of the plurality of conductive elements 218 in the composite core 212 may be equal to or less than 0.6% by weight. In some embodiments, a quantity of the plurality of conductive elements 218 in the composite core 212 may be equal to or less than 0.5% by weight. In some embodiments, a quantity of the plurality of conductive elements 218 in the composite core 212 may be equal to or less than 0.4% by weight. In some embodiments, a quantity of the plurality of conductive elements 218 in the composite core 212 may be equal to or less than 0.3% by weight.

In some embodiments, a quantity of the plurality of conductive elements 218 in the composite core 212 is at most about 5.0% by weight. In some embodiments, a quantity of the plurality of conductive elements 218 in the composite core 212 is at most about 4.5% by weight. In some embodiments, a quantity of the plurality of conductive elements 218 in the composite core 212 is at most about 4.0% by weight. In some embodiments, a quantity of the plurality of conductive elements 218 in the composite core 212 is at most about 3.5% by weight. In some embodiments, a quantity of the plurality of conductive elements 218 in the composite core 212 is at most about 3.0% by weight. In some embodiments, a quantity of the plurality of conductive elements 218 in the composite core 212 is at most about 2.5% by weight. In some embodiments, a quantity of the plurality of conductive elements 218 in the composite core 212 is at most about 2.0% by weight. In some embodiments, a quantity of the plurality of conductive elements 218 in the composite core 212 is at most about 1.5% by weight. In some embodiments, a quantity of the plurality of conductive elements 218 in the composite core 212 is at most about 1.0% by weight. In some embodiments, a quantity of the plurality of conductive elements 218 in the composite core 212 is at most about 0.5% by weight. In some embodiments, a quantity of the plurality of conductive elements 218 in the core 212 may be in a range of about 0.1% to about 1% by weight, inclusive (e.g., about 0.1%, 0.2%, 0.3, 0.4%, 0.5%, 0.6%, 0.7%, 0.8%, 0.9%, or about 1.0% by weight, inclusive).

In some embodiments, the conductive elements 218 includes conductive filaments or conductive tows having a length in a range of about 10 microns to about 50 microns, inclusive (e.g., about 10, 15, 20, 25, 30, 35, 40, 45, or 50 microns, inclusive). In some embodiments, the conductive elements 218 includes conductive filaments or conductive tows having a length of at least about 5 microns. In some embodiments, the conductive elements 218 includes conductive filaments or conductive tows having a length of at least about 10 microns. In some embodiments, the conductive elements 218 includes conductive filaments or conductive tows having a length of at least about 15 microns. In some embodiments, the conductive elements 218 includes conductive filaments or conductive tows having a length of at least about 20 microns. In some embodiments, the conductive elements 218 includes conductive filaments or conductive tows having a length of at least about 25 microns. In some embodiments, the conductive elements 218 includes conductive filaments or conductive tows having a length of at least about 30 microns. In some embodiments, the conductive elements 218 includes conductive filaments or conductive tows having a length of at least about 35 microns. In some embodiments, the conductive elements 218 includes conductive filaments or conductive tows having a length of at least about 40 microns. In some embodiments, the conductive elements 218 includes conductive filaments or conductive tows having a length of at least about 45 microns. In some embodiments, the conductive elements 218 includes conductive filaments or conductive tows having a length of at most about 50 microns. In some embodiments, the conductive elements 218 includes conductive filaments or conductive tows having a length of at most about 45 microns. In some embodiments, the conductive elements 218 includes conductive filaments or conductive tows having a length of at most about 40 microns. In some embodiments, the conductive elements 218 includes conductive filaments or conductive tows having a length of at most about 35 microns. In some embodiments, the conductive elements 218 includes conductive filaments or conductive tows having a length of at most about 30 microns.

In some embodiments, in addition to the conductive elements 218 being included in the core 212, conductive fillers or conductive additives may be included in the composite matrix (e.g., resin matrix) that forms a bulk volume of the core 212. Suitable conductive fillers or conductive additives that may be included in the composite matrix so as to be a part of the composite matrix can include, but are not limited to carbon black particles, graphene particles, CNTs, silver nanoparticles, copper nanoparticles, gold particles, aluminum particles, nickel particles, zinc particles, iron oxide particles, indium tin oxide (ITO) particles, any other suitable conductive particles or any suitable combination thereof.

In some embodiments, a conductivity of the plurality of conductive elements 218 may be in a range of about 10² S/m to about 108 S/m, inclusive (e.g., about 10², 10³, 10⁴, 10⁵, 10⁶, 10⁷, or about 10⁸ S/m, inclusive of all ranges and values therebetween). In some embodiments, a conductivity of the plurality of conductive elements 218 may be at least about 10² S/m. In some embodiments, a conductivity of the plurality of conductive elements 218 may be at least about 10³ S/m. In some embodiments, a conductivity of the plurality of conductive elements 218 may be at least about 10⁴ S/m. In some embodiments, a conductivity of the plurality of conductive elements 218 may be at least about 10⁵ S/m. In some embodiments, a conductivity of the plurality of conductive elements 218 may be at least about 10⁶ S/m.

In some embodiments, a specific conductivity of the plurality of conductive elements 218 may be in a range of about 500 Sm²/kg to about 10,000 Sm²/kg, inclusive (e.g., about 500, 1,000, 1,500, 2,000, 2,500, 3,000, 3,500, 4,000, 4,500, 5,000, 5,500, 6,000, 6,500, 7,000, 7,500 8,000, 8,500 9,000, 9,500, or about 10,000 Sm²/kg, inclusive). In some embodiments, the specific conductivity of the plurality of conductive elements 218 may be at least 500 Sm²/kg. In some embodiments, the specific conductivity of the plurality of conductive elements 218 may be at least 1,000 Sm²/kg. In some embodiments, the specific conductivity of the plurality of conductive elements 218 may be at least 1,500 Sm²/kg. In some embodiments, the specific conductivity of the plurality of conductive elements 218 may be at least 2,000 Sm²/kg. In some embodiments, the specific conductivity of the plurality of conductive elements 218 may be at least 2,500 Sm²/kg. In some embodiments, the specific conductivity of the plurality of conductive elements 218 may be at least 3,000 Sm²/kg. In some embodiments, the specific conductivity of the plurality of conductive elements 218 may be at least 3,500 Sm²/kg. In some embodiments, the specific conductivity of the plurality of conductive elements 218 may be at least 4,000 Sm²/kg. In some embodiments, the specific conductivity of the plurality of conductive elements 218 may be at least 4,500 Sm²/kg. In some embodiments, the specific conductivity of the plurality of conductive elements 218 may be at least 5,000 Sm²/kg. In some embodiments, the specific conductivity of the plurality of conductive elements 218 may be at least 5,500 Sm²/kg. In some embodiments, the specific conductivity of the plurality of conductive elements 218 may be at least 6,000 Sm²/kg. In some embodiments, the specific conductivity of the plurality of conductive elements 218 may be at least 6,500 Sm²/kg. In some embodiments, the specific conductivity of the plurality of conductive elements 218 may be at least 7,000 Sm²/kg. In some embodiments, the specific conductivity of the plurality of conductive elements 218 may be at least 7,500 Sm²/kg. In some embodiments, the specific conductivity of the plurality of conductive elements 218 may be at least 8,000 Sm²/kg. In some embodiments, the specific conductivity of the plurality of conductive elements 218 may be at least 8,500 Sm²/kg. In some embodiments, the specific conductivity of the plurality of conductive elements 218 may be at least 9,000 Sm²/kg. In some embodiments, the specific conductivity of the plurality of conductive elements 218 may be at least 9,500 Sm²/kg. In some embodiments, the specific conductivity of the plurality of conductive elements 218 may be at least 10,000 Sm²/kg.

Inclusion of the conductive elements 218 in the core 212 advantageously causes the core 212 to be conductive such that the core 212 has a resistance that is equal to or less than 50% of a resistance of a comparable core that does not include the plurality of conductive elements 218. In some embodiments, the core 212 has a resistance that is equal to or less than 40% of a resistance of a comparable core that does not include the plurality of conductive elements 218. In some embodiments, the core 212 has a resistance that is equal to or less than 35% of a resistance of a comparable core that does not include the plurality of conductive elements 218. In some embodiments, the core 212 has a resistance that is equal to or less than 30% of a resistance of a comparable core that does not include the plurality of conductive elements 218. In some embodiments, the core 212 has a resistance that is equal to or less than 25% of a resistance of a comparable core that does not include the plurality of conductive elements 218. In some embodiments, the core 212 has a resistance that is equal to or less than 20% of a resistance of a comparable core that does not include the plurality of conductive elements 218.

In some embodiments, the core 212 may have a resistance of less than about 2 ohms. In some embodiments, the core 212 has a resistance that is at most 50% of a resistance of a comparable core that does not include the plurality of conductive elements 218 (e.g., a pure carbon core). In some embodiments, the core 212 has a resistance that is at most 45% of a resistance of a comparable core that does not include the plurality of conductive elements 218. In some embodiments, the core 212 has a resistance that is at most 40% of a resistance of a comparable core that does not include the plurality of conductive elements 218. In some embodiments, the core 212 has a resistance that is at most 35% of a resistance of a comparable core that does not include the plurality of conductive elements 218. In some embodiments, the core 212 has a resistance that is at most 30% of a resistance of a comparable core that does not include the plurality of conductive elements 218. In some embodiments, the core 212 has a resistance that is at most 25% of a resistance of a comparable core that does not include the plurality of conductive elements 218. In some embodiments, the core 212 has a resistance that is at most 20% of a resistance of a comparable core that does not include the plurality of conductive elements 218. In some embodiments, the core 212 has a resistance that is in a range of about 20% to about 50%, inclusive (e.g., about 20%, 25%, 30%, 35%, 40%, 45%, or 50%, inclusive) of a resistance of a comparable core that does not include the plurality of conductive elements 218.

In some embodiments, a ratio of a resistivity of the core 212 with the plurality of conductive elements 218 to a resistivity of a core that does not include the plurality of conductive elements 218 is equal to or less than 1:2. In some embodiments, a ratio of a resistivity of the core 212 with the plurality of conductive elements 218 to a resistivity of a core that does not include the plurality of conductive elements 218 is equal to or less than 0.9:2. In some embodiments, a ratio of a resistivity of the core 212 with the plurality of conductive elements 218 to a resistivity of a core that does not include the plurality of conductive elements 218 is equal to or less than 0.8:2. In some embodiments, a ratio of a resistivity of the core 212 with the plurality of conductive elements 218 to a resistivity of a core that does not include the plurality of conductive elements 218 is equal to or less than 0.7:2. In some embodiments, a ratio of a resistivity of the core 212 with the plurality of conductive elements 218 to a resistivity of a core that does not include the plurality of conductive elements 218 is equal to or less than 0.6:2. In some embodiments, a ratio of a resistivity of the core 212 with the plurality of conductive elements 218 to a resistivity of a core that does not include the plurality of conductive elements 218 is equal to or less than 0.5:2. In some embodiments, a ratio of a resistivity of the core 212 with the plurality of conductive elements 218 to a resistivity of a core that does not include the plurality of conductive elements 218 is equal to or less than 0.4:2. In some embodiments, a ratio of a resistivity of the core 212 with the plurality of conductive elements 218 to a resistivity of a core that does not include the plurality of conductive elements 218 is equal to or less than 0.3:2. In some embodiments, a ratio of a resistivity of the core 212 with the plurality of conductive elements 218 to a resistivity of a core that does not include the plurality of conductive elements 218 is equal to or less than 0.2:2. In some embodiments, a ratio of a resistivity of the core 212 with the plurality of conductive elements 218 to a resistivity of a core that does not include the plurality of conductive elements 218 is equal to or less than 0.1:2. In some embodiments, a ratio of a resistivity of the core 212 with the plurality of conductive elements 218 to resistance of a comparable core that does not include the plurality of conductive elements 218 is in a range of about 0.1:2 to about 1:2, inclusive.

The core 212 may have any suitable cross-sectional width (e.g., diameter). In some embodiments, the core 212 has a diameter in a range of about 2 mm to about 15 mm, inclusive (e.g., 2, 3, 4, 5, 6, 7, 8, 9, 10, 11, 12, 13, 14, or 15 mm, inclusive), or any other suitable diameter as described in detail with respect to the core 212. In some embodiments, the core 212 may have a glass transition temperature (e.g., for thermoplastic composites), or melting point (e.g., for thermoset composites) of at least about 70 degrees Celsius (e.g., at least 75, at least 80, at least 90, at least 100, at least 120, at least 140, at least 150, at least 160, at least 180, at least 200, at least 220, at least 240, or at least 250, degrees Celsius, inclusive). The glass transition temperature or melting point of the core 212 may correspond to a threshold operating temperature of the conductor 200, which may limit the ampacity of the conductor 200. In other words, a maximum amount of current that can be delivered through the conductor 200 is the current at which the operating temperature of the conductor 200, or at least the temperature of the core 212 is less than the glass transition temperature or melting point of the composite core 212.

In some embodiments, the core 212 defines a circular cross-section. In some embodiments, the core 212 may define an ovoid, elliptical, polygonal, or asymmetrical cross-section. In some embodiments, the strength member 210 may include a single core 212. In other embodiments, the strength member 210 may include multiple cores, for example, 2, 3, 4, or even more, with optionally, the encapsulation layer 214 being disposed around the multiple cores or around each individual core. In such embodiments, each of the multiple cores may be substantially similar to each other, or at least one of the multiple cores may be different from the other cores (e.g., have a different size, different shape, formed from a different material, have components embedded therein, etc.).

In some embodiments, the core 212 is solid, i.e., does not include any holes or voids therein other than a de minimis amount of naturally occurring voids or porosities that may form during a fabrication process of the core 212. In some embodiments, the core 212 may be hollow, for example, define one or more deliberately formed channels or voids therein or therethrough (e.g., extending axially along and/or defined about a longitudinal axis of the strength member 210). Sensing or transmission components may be embedded within the void or channels defined in the core 212. For example, in some embodiments, sensors such as strain gages, accelerometers, or optical fiber sensors may be disposed within, or extend through the core 212. The sensors may be configured to sense various operating parameters of the conductor 200, as described in detail with respect to the core 112.

In some embodiments, the encapsulation layer 214 may be disposed around the core 212, for example, circumferentially around the core 212. In some embodiments, an insulation layer (not shown) may optionally be interposed between the core 212 and the encapsulation layer 214, for example, as described with respect to the conductor 100, and therefore, not described in further detail herein. The encapsulation layer 214 may be formed from any suitable electrically conductive or non-conductive material. In some embodiments, the encapsulation layer 214 may be formed from a conductive material including, but not limited to aluminum (e.g., 1350-H19), annealed aluminum (e.g., 1350-0), aluminum alloys (e.g., Al—Zr alloys, 6000 series Al alloys such as 6201-TSl, -T82, -T83, 7000 series Al alloys, 8000 series Al alloys, etc.), copper, copper alloys (e.g., copper magnesium alloys, copper tin alloys, copper micro-alloys, etc.), any other suitable conductive material, or any combination thereof. In some embodiments, the encapsulation layer 214 is formed from Al and is optionally pretensioned, i.e., is under tensile stress after being disposed on the core 212. The encapsulation layer 214 may be substantially similar to the encapsulation layer 114 and may be formed using any suitable process as described with respect to the encapsulation layer 114.

In some embodiments, the interface between the core 212 and the encapsulation layer 214 may optionally include surface features, for example, grooves, slots, notches, indents, detents, etc. to enhance adhesion, bonding and/or interfacial locking between a radially outer surface of the core 212 and a radially inner surface of the encapsulation layer 214. Such surface features may facilitate retention and preservation of the stress from pretensioning in the encapsulation layer 214. In some embodiments, the composite core 212 may have a glass fiber tow disposed around its outer surface to create a screw shape or twisted surface. In some embodiments, a braided or woven fiber layer is applied in the outer layer of the core 212 to promote interlocking or bonding between the core 212 and the encapsulation layer 214.

In some embodiments, the encapsulation layer 214 may have a thickness in a range of about 0.3 mm to about 5 mm, inclusive, or even higher (e.g., 0.3, 0.5, 1, 1.5, 2.0, 2.5, 3.0, 3.5, 4.0, 4.5, 5.0 mm, inclusive, or even higher). In some embodiments, a ratio of an outer diameter of the encapsulation layer 214 to an outer diameter of the core 212 is in range of about 1.2:1 to about 5:1, inclusive (e.g., 1.2:1, 1.5:1, 2:1, 2.5:1, 3:1, 3.5:1, 4:1, 4.5:1, or 5:1, inclusive).

In some embodiment, the strength member 210 may have a minimum level of tensile strength, for example, at least 600 MPa (e.g., at least 600, at least 700, at least 800, at least 1,000, at least 1,200, at least 1,400, at least 1,600, at least 1,800, or at least 2,000 MPa). In some embodiments, the elongation during pretension of the strength member 210 may include elongation by at least 0.01% strain (e.g., at least 0.01%, at least 0.05%, at least 0.1%, at least 0.15%, at least 0.2%, at least 0.25%, at least 0.3%, at least 0.35%, at least 0.4%, at least 0.45%, or at least 0.5% strain, inclusive) depending on the type of strength members and the degree of knee point reduction, and the strength member 210 may be pre-tensioned before or after entering the conforming machine. Moreover, the strength member 210 may be configured to endure radial compression from crimping of conventional fittings as well as radial pressure during conforming of drawing down process or folding and molding of at least 3 kN (e.g., at least 3, at least 4, at least 5, at least 10, at least 15, at least 20, or at least 25 kN, inclusive), for example, for composite cores 212 with little to substantially no plastic deformation.

In some embodiments, the encapsulation layer 214 may have an outer surface that is configured to be smooth and shiny, for example, may include or be substantially similar to any of the encapsulation layers described in the '721 patent. In some embodiments, the outer surface of the encapsulation layer 214 may be surface treated (e.g., plasma treated, texturized, etc.) to have the absorptivity or reflectivity as described above. In some embodiments, the strength member 210, i.e., the outer surface of the encapsulation layer 214 may be optionally coated with an inner coating (not shown) to reduce solar absorptivity. For example, the inner coating may be disposed between the encapsulation layer 214 and the conductor layer 220. Examples of such inner coatings are described in detail in the '721 patent and incorporated by reference herein.

A conductor layer 220 is disposed around the strength member 210 and configured to transmit electrical signals therethrough In some embodiments, the conductor layer 220 may include a plurality of strands of a conductive material that includes or is formed from a low resistance material disposed around the strength member 210. For example, the conductor layer 220 may include a first set of conductive strands disposed around the strength member 210 in a first wound direction (e.g., wound helically around the strength member 210 in a first rotational direction), a second set of conductive strands disposed around the first set of strands in a second wound direction (e.g., wound helically around the first set of conducive strands in a second rotational direction opposite the first rotational direction), and may also include a third set of strands wound around the second set of strands in the first wound direction, and may further include any number of additional strands as desired.

In some embodiments, the conductor layer 220 may include Z shaped strands. In some embodiments, the conductor layer 220 may include S shaped strands. In some embodiments, the conductor layer 220 may be substantially similar to the conductor layer 120.

In some embodiments, the conductor layer 220 (e.g., a plurality of strands of conductive material) may include a low resistance material that has a resistivity of less than 10⁻¹⁰ Ω·cm over an operating temperature in a range of from about −40 degrees Celsius to about 250 degrees Celsius. In some embodiments, the conductor layer 220 (e.g., a plurality of strands of conductive material) may include a superconductor or superconductor like material. In some embodiments, the conductor layer 220 (e.g., a plurality of strands of conductive material) may include an alloy including a superconductor or superconductor like material. In some embodiments, the conductor layer 220 may include a precompressed metal or alloy. That is, a metal or an alloy may be compressed under a certain amount of pressure prior to be disposed on the encapsulation layer 214.

In some embodiments, the conductor layer 220 may further include conductive strands including Z, C or S wires to keep the outer strands in place. The conductor layer 220 may have any suitable cross-sectional shape, for example, circular, triangular, trapezoidal, etc. In some embodiments, the conductor layer 220 may further include a stranded aluminum layer that may be round or trapezoidal.

In some embodiments, the strength member 210 may be optionally tensioned while the conductor layer 220 disposed around the strength member 210 may be applied to cause the conductor 200 to form a cohesive conductive hybrid rod that is spoolable onto a conductor reel. In some embodiments, to facilitate conductor spooling onto a reel and conductor spring back at ease, the conductor 200 may be optionally configured to be non-round (e.g., elliptical) such that the shorter axis (in conductor 200) is subjected to bending around a spool (or a sheaves wheel during conductor installation) to facilitate a smaller bend or spool radius, while the strength members 210 may be configured to have a longer axis facilitate spring back for installation. The overall conductor 200 may be round with non-round strength member 210 or multiple strength members 210 arranged to be non-round, and the spooling bending direction may be along the long axis of the strength member 210 to facilitate spring back while not overly subjecting the conductor layer 220 with additional compressive force from spooling bending.

To further facilitate spooling of the conductor layer 220 on the strength member 210, in some embodiments, the conductor layer 220 may include multiple segments, for example, strands or sets of strands or wires of conductive material (e.g., 2, 3, 4, etc.), and each segment bonded to strength member 210 while retaining compressive stress, and the segments rotates one full rotation or more along the conductor 200 length (equal to one full spool in a reel) to facilitate easy spooling. Thus, the conductor 200 may be configured to have negligible skin effect (i.e., conducting layer thickness is less than the skin depth required at AC circuit frequency), with the strength member 210 may be under sufficient residual tensile stress, and the conductor layer 220 (e.g., each of the strands of the conductive material) are mostly free of tension or under compressive stress. In some embodiments, the strands of the conductive material (i.e., a low resistance material) may be formed from a conforming machine, for example, by extruding hot deformable (e.g., semi solid) conductive material from a mold. The strands can be molded to be round, trapezoidal, or any other desirable shape. In some embodiments, the extrusion mold or die may have a stranding lay ratio defined therein so that during the stranding operation of the conductive strands, no shaping may be needed (e.g., removing of sharp corners or edges of the conductive strands to avoid corona as is performed in conventional stranding operations). In some embodiments, the conductive media may be extruded out of the mold or die at an angle so as to form conductive strands that wrap around the strength member 210 at an angle, as described herein.

In some embodiments, for AC applications where skin effect is prominent, the conductor layer 220 may include a plurality of layers of conductive strands disposed concentrically around the strength member 210, with each layer being of finite thickness to maximize skin effect for lowest AC resistance at minimal conductor content. In some embodiments, the conductor layer 220 may be optionally stranded to facilitate conductor spooling around a reasonably sized spool and facilitate conductor stringing. In some embodiments, the outer most strands included in the conductor layer 220 may be TW, C, Z, S, or round strands, as it will not cause permanent bird caging problem (i.e., the inner strands of the conductor layer 220 may not be deformed such that they prevent the outer strands from proper resettlement after tension is released or reduced). Accordingly, the smooth outer surface and the compact configuration can effectively reduce the wind load and ice accumulation on the conductor 200, resulting in less sag from ice or wind related weather events.

The conductor layer 220 may be under no substantial tension while the strength member 210 may be pre-stretched/tensioned. After the pre-tension in the strength member 210 is released, the conductor layer 220 may be subjected to compression, which may minimize the shrinking back of the strength member 210. The strength member 210 made with composite materials may have a strength above 80 ksi, and a modulus ranging from 5 msi to 40 msi, and a CTE of about 1×10⁻⁶/° C. to about 8×10⁻⁶/° C., inclusive. In some embodiments, an insulator layer 222 (e.g., a jacket) may optionally be disposed around the conductor layer 220. The insulator layer 222 may be formed from any suitable electrically insulative material, for example, rubber, plastics, or polymers (e.g., polyethylene, PTFE, high density polyethylene, cross-linked high density polyethylene, etc.). The insulator layer 222 may be configured to electrically isolate or shield the conductor 200. In some embodiments, the insulator layer 222 may be excluded.

In some embodiments, an outer surface of the conductor layer 220 (e.g., outer surface of the outermost conductive strands or an outer surface of each of the conductive strands) or the insulator layer is treated with features and/or include features to cause the outer surface to have a solar absorptivity of less than 0.6 (e.g., less than 0.55, less than 0.5, less than 0.45, less than 0.4, less than 0.35, less than 0.3, less than 0.25, less than 0.2, less than 0.15, or less than 0.1, inclusive). In some embodiments, the outer surface has a solar absorptivity of less than 0.55.

In some embodiments, the outer surface of the conductor layer 220 may be treated or otherwise configured to have a reflectivity of less than 50% corresponding to an operating temperature of greater than 90 degrees Celsius, as described in detail with respect to the conductor layer 220. In some embodiments, an outer coating may be disposed on the outer surface of the conductor layer 220 in addition to, or alternatively to the outer surface being treated of the conductor layer, as described herein. The outer coating may include any outer coating as described with respect to the conductor 100 or any outer coating described in the '721 patent.

Similar to the conductor 100, the conductor 200 including the conductive core 212 may provide several advantages over comparable conductors that have cores that do not include the plurality of conductive elements 218, that are non-conductive or insulative, or that have a resistance that is at least 2, 3, 5, 7, 9, 11, 20, 50, 100, 200, 500, 1000, 10⁴, 10⁵ times of the resistance of the material used to form the conductor layer 220 (e.g., 100× the resistance of a low resistance material). For example, the conductor 200 may have greater conductivity, greater ampacity, and lesser line loss relative to comparable conductors that do not include a conductive core, without the weight increase and increased sag, for example, as described with respect to the conductor 100.

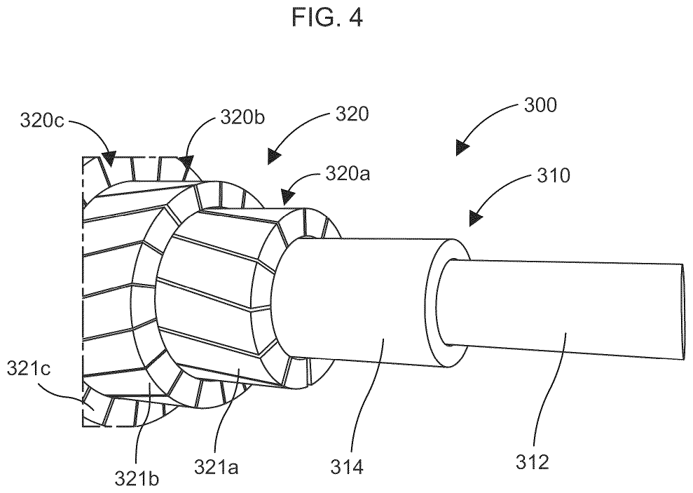

FIG. 4 is a perspective view of a conductor 300, according to an embodiment. The conductor 300 is similar to the conductor 200 and includes a strength member 310 including a core 312 having an encapsulation layer 314, that may be substantially similar to the core 112, 212, and the encapsulation layer 114, 214, respectively, as previously described. The core 312 includes a plurality of conductive elements (e.g., the conductive elements 118 or 218) disposed or included therein, as described herein. The conductor 300 also includes a conductor layer 320 disposed around strength member 310. The conductor 300 includes a conductor layer 320 that includes a first layer 320a including first conductive strands 321a dispose on the encapsulation layer 314 of the strength member 310, a second layer 320b including second conductive strands 321b disposed on the first layer 320a, and a third layer 320c including third conductive strands 321c disposed on the second layer 320b. Each of the first conductive strands 321a, the second conductive strands 321b, and the third conductive strands 321c may be formed from a low resistance material (e.g., a superconductor or superconductor like material), aluminum, aluminum alloy, copper or copper alloy including micro alloy as conductive media, any other conductive material or a combination thereof as described herein.

As shown in FIG. 4, the first conductive strands 321a include trapezoidal strands that are stranded, disposed, or otherwise oriented on the strength member 310 in a first angular orientation or first wound direction along an axial length of the conductor 300. The second conductive strands 321b also include trapezoidal strands that are stranded, disposed, or otherwise oriented on the first layer 320a formed by the first conducive strands 321a in a second angular orientation or second wound direction that is different from the first orientation or first wound direction (e.g., oriented at an opposite angle to the first orientation) along the axial length of the conductor 300. Moreover, the third conductive strands 321c also include trapezoidal strands that are stranded, disposed, or otherwise oriented on the second layer 320b formed by the second conducive strands 321b in a third angular orientation or third wound direction that is different from the second orientation or second wound direction (e.g., oriented at an opposite angle to the second orientation or in the same or substantially the same orientation as the first orientation) along the axial length of the conductor 300.

Providing trapezoidal strands allows close packing of the conductive strands 321a, 321b, 321c within their respective conductor layers 320a, 320b, 320c which enables better utilization of the surface area of the conductor 300 for electrical energy transmission. Including multiple layers 320a, 320b, and 320c in the conductor 300 provides multiple paths for electrical energy transmission providing redundancy, and a larger surface area for energy transmission. Moreover, having multiple conductive layers 320a, 320b, and 320c oriented in opposing orientations also increases the mechanical strength of the conductor 300. It should be appreciated that while FIG. 4 shows the conductive strands 321a, 321b, and 321c as having a trapezoidal cross-sectional shape, in other embodiments, the conductive strands 321a, 321b, and 321c may have any other suitable cross-sectional shape, for example, a Z cross-sectional shape, a C cross-sectional shape, a S cross-sectional shape, a circular shape, a triangular shape, any other suitable shape or a combination thereof.

In some embodiments, one or more of the conductive layers 320a, 320b, 320c of the conductor layer 320 may include a low resistance material and other of the layers 320a, 320b, 320c may be conjured to exert pressure on the layer including the low resistance material. For example, the inner most conductive layer 320a may include the low resistance material, and the outer layers 320b and/or 320c may be configured to exert a pressure on the inner most conductive layers 320a. In some embodiments, the conductor layer 320 may further include an additional pressurizing layer (not shown) disposed on the third conductive layer 320c. The pressurizing layer may exert a predetermined pressure on the conductive layers 320a, 320b, 320c. In such embodiments, each of the conductive layers 320a, 320b, 320c may include the low resistance material.

Pressurizing may cause at least one of the first conductive layer 320a, the second conductive layer 320b, or the third conductive layer 320c to be pressurized at a pressure of more than about 20 GPa, more than about 15 GPa, more than about 10 GPa, more than about 5 GPa, more than about 2 GPa, more than about 1 GPa, more than about 500 MPa, more than about 250 MPa, more than about 150 MPa, more than about 100 MPa, more than about 10 MPa, more than about 1 MPa, more than about 500 kPa, more than about 300 kPa, or more than about 200 kPa. Pressurizing the conductive layer 320 (i.e., 320a, 320b and 320c) may lead to decrease in resistivity of the conductor layer 320, as previously described herein. In some embodiments, the pressurizing layer may be disposed on the first conductive layer 320a. In some embodiments, the pressurizing layer may be disposed on the second conductive layer 320b. The encapsulation layer 314 may prevent damage to the core 312 from the pressure exerted by the pressurizing layer.

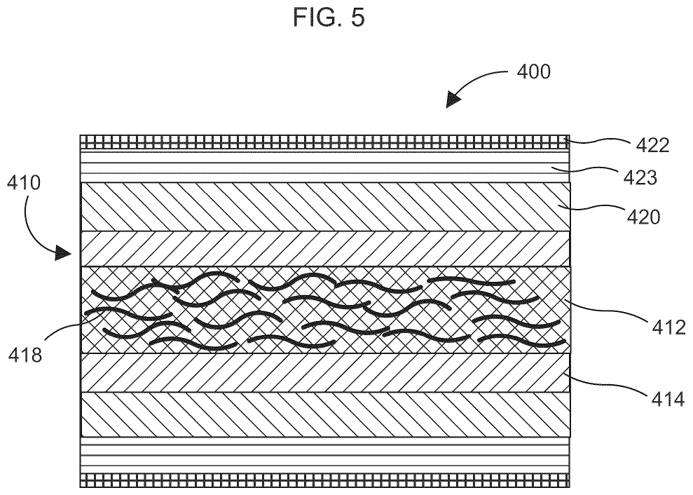

FIG. 5 is a side cross-section view of a conductor 400, according to an embodiment, The conductor 400 includes a strength member 410, a conductor layer 420 disposed around the strength member 410, a pressurizing layer 423 and optionally, an insulator layer or jacket 422 disposed on the conductor layer 420.

The strength member 410 includes a core 412, for example, a composite core, and optionally, an encapsulation layer 414 disposed around the core 412, for example, disposed circumferentially around the core 412. The core 412 having an encapsulation layer 414, that may be substantially similar to the core 112, 212, and the encapsulation layer 114, 214, respectively, as previously described, and therefore, not described in further detail herein.

The conductor layer 420 may be formed from a low resistance material (e.g., a superconductor), aluminum, aluminum alloy, copper or copper alloy including micro alloy as conductive media, any other conductive material or a combination thereof as described herein. In some embodiments, the conductor layer 420 is similar to the conductor layer 120 and 220 described in connection with FIG. 1 and FIG. 2, respectively.

In some embodiments, the conductor 400 includes a pressurizing layer 423 disposed on the conductive layer 420. The pressurizing layer may be in a form of any pressurized enclosure that may be used to exert a controlled pressure on the conductive layer 420. In some embodiments, the pressurizing layer 423 may be in a form of a sealed pressurizing jacket filled with a pressurized gas or fluid. In some embodiments, the pressurizing layer 423 may include an oil (e.g., a silicone oil) as a pressurized fluid. In some embodiments, the pressurized fluid may also function as a dielectric and/or coolant. In some embodiments, the pressurizing layer 423 may be in a form of pressurized hose that encapsulates the conductor layer 420 and the strength member 410.

The encapsulation layer 414 may prevent damage of the core 412 from the pressure exerted by the pressurizing layer 423. Pressurizing may cause conductive layer 420 to have higher pressures (e.g., more than about 20 GPa, more than about 15 GPa, more than about 10 GPa, more than about 5 GPa, more than about 2 GPa, more than about 1 GPa, more than about 500 MPa, more than about 250 MPa, more than about 150 MPa, more than about 100 MPa, more than about 10 MPa, more than about 1 MPa, more than about 500 kPa, more than about 300 kPa, or more than about 200 kPa) that may lead to decrease in resistivity of the conductor layer 420. Without bound by the theory, for example, pressurizing may cause an increase in the critical temperature Tc of a superconductor material that may be included in the conductor layer 420. Pressurizing may also cause decrease in an electron-phonon coupling constant, λ, of a metal conductor, which may lead to decrease in resistivity.

In some embodiments, the pressurizing layer 423 may have an outer surface that is configured to be smooth and shiny (e.g., surface treated) so as to reduce absorptivity (i.e., enhance reflectivity) thus reducing an operating temperature of the conductor 400.

In some embodiments, the conductor 400 may further include an insulator layer 422 (e.g., a jacket) may be disposed around the pressurizing layer 423. The insulator layer 422 may be formed from any suitable electrically insulative material, for example, rubber, plastics, or polymers (e.g., polyethylene, PTFE, high density polyethylene, cross-linked high density polyethylene, etc.). The coating 422 may be configured to electrically isolate or shield the conductor 400. In some embodiments, the insulator layer 422 may be excluded.

FIG. 6 is a schematic flow chart of a method 500 for fabricating a conductor (e.g., the conductor 100, 200, 300, 400) that includes a strength member (e.g., the strength member 110, 210, 310, 410) having a core (e.g., the core 112, 212, 312, 412) that includes a plurality of conductive elements (e.g., the conductive elements 118, 218) making the core conductive, and a conductor layer (e.g., the conductor layer 120, 220, 320, 420) disposed on the strength member, according to an embodiment. While described with respect to the conductor 100, it should be appreciated that the method can be used to form any composite conductor including a zero-resistant material, as described herein.

The method 500 includes forming the core 112 from a composite material that includes the plurality of conductive elements 118 mixed, disposed, or included therein, at 502. The composite material may include any suitable composite material as described with respect to the conductor 100, and the core 112 may be formed using any suitable method described with respect to the conductor 100. In some embodiments, the core 112 may be formed using pultrusion, which is a combination of pull and extrusion and provides a low cost method for forming the core 112. In other embodiments, the core 112 may be formed using extrusion, casting, any other suitable method or a combination thereof.

In some embodiments, the method 500 may include disposing the encapsulation layer 114 on the composite core 112 to form a strength member, at 504. In some embodiments, the encapsulation layer 114 may be formed from a conductive material (e.g., Al, Al alloys, Cu, steel, or any other suitable described herein) or a non-conductive material such as plastics, polymers, rubbers, silicone, etc. Moreover, the encapsulation layer 114 may be disposed around the core 112 using a conforming machine or any other suitable method, as described with respect to the conductor 100.

At 506, the one or more conductive layers (e.g., one or conductive strands) are disposed on the strength member 110 to form the conductor layer 120, thus forming the conductor 100. The conductive strands may be disposed around strength member 110 using a conforming machine or any suitable method, as described herein. In some embodiments, the conductor layer 120 may include a first set of conductive strands disposed around the strength member 110 in a first wound direction (e.g., wound helically around the strength member 110 in a first rotational direction), a second set of conductive strands disposed around the first set of strands in a second wound direction (e.g., wound helically around the first set of conducive strands in a second rotational direction opposite the first rotational direction), and may also include a third set of strands wound around the second set of strands in the first wound direction. The conductive layers (e.g., the conductive strands 321a, 321b, 321c) may be formed using conforming, extrusion, or any other suitable process. The conductive strands may be formed from a low resistance material (e.g., a superconductor or superconductor like material), aluminum, aluminum alloy, copper or copper alloy including micro alloy as conductive media, etc. In some embodiments, conductive strands may include a superconductor or superconductor like material. In some embodiments, the conductive strands including Z, C, or S wires to keep the outer strands in place. The conductive strands may have any suitable cross-sectional shape, for example, circular, triangular, trapezoidal, etc. In some embodiments, the conductive strands may be round or trapezoidal strands. In some embodiments, the conductive strands may include Z shaped strands. In some embodiments, the conductive strands may include S shaped strands.

In some embodiments, an outer surface of the conductor layer 120 (e.g., an outer surface of each conductive strand, or a radially outer surface of only the outer most conductive strands included in the conductor layer 120) is treated, at 508, as previously described herein with respect to the conductor 100.

In some embodiments, a pressurizing layer may be disposed on the conductor layer 120 to encapsulate the conductor layer 120, at 510. The pressurizing layer is similar to the pressurizing layer, as previously described herein with respect to the conductor 400, and the pressurizing layer can be disposed by using any suitable method available in the art. For example, methods for creating a hermetic seal or a pressurizing jacket to encase an electric wire used in the art might be appropriate.

In some embodiments, the insulator layer 122 may be disposed around the conductor layer 120, at 512. In some embodiments, the insulator layer 122 may be disposed around the pressurizing layer that may be disposed on the conductor layer 120.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes, and omissions may also be made in the design, operating conditions, and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Thus, particular implementations of the invention have been described. Other implementations are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

What is claimed is:

1. An apparatus, comprising:
a strength member, including:
a core including a composite material; and
an encapsulation layer disposed around the core; and
a conductor layer disposed around the strength member, the conductor layer including a low resistance material having a resistivity of less than 10⁻¹⁰ Ω·cm over an operating temperature in a range of about −40 degrees Celsius about 250 degrees Celsius.

2. The apparatus of claim 1, wherein the operating temperature is in a range of about −30 degrees Celsius to about 200 degrees Celsius.

3. The apparatus of claim 1, wherein the operating temperature is in a range of about −20 degrees Celsius to about 180 degrees Celsius.

4. The apparatus of claim 1, wherein the operating temperature is in a range of −10 degrees Celsius to about 160 degrees Celsius.

5. The apparatus of claim 1, wherein the low resistance material includes a superconductor or a superconductor like material.

6. The apparatus of claim 5, wherein the superconductor or superconductor like material has a critical temperature of about 30 degrees Celsius or greater under ambient pressure.

7. The apparatus of claim 6, wherein the superconductor or superconductor like material includes a ceramic compound.

8. The apparatus of claim 1, wherein the low resistance material includes a compound of Formula I,
$${A}_{a} {{B}_{b} ( {E O}_{4} )}_{c} {X}_{d} \qquad ( I )$$
or a salt, hydrate, solvate, enantiomer, stereoisomer, or tautomer thereof,
wherein,
A is Ca, Ba, Sr, Sn, Pb, Y, La, Ce or combinations thereof;
B is Cu, Cd, Zn, Mn, Fe, Ni, Ag or a combination thereof;
E is P, As, V, Si, B, S or a combination thereof;
X is F, Cl, OH, O, S, Se, Te or a combination thereof;
each a and b is individually and independently selected from any number from 0 to 10;
c is individually and independently selected from any number from 0 to 6; and
d is individually and independently selected from any number from 0 to 4.

9. The apparatus of claim 1, wherein the low resistance material includes a compound of Formula II,
$${MX}_{n} or {X}_{n} M , \qquad ( II )$$
or salts thereof,
wherein:
M is at least one of sulfur(S), thorium (Th), protactinium (Pa), uranium (U), Neptunium (Np), plutonium (Pu), americium (Am), curium (Cm), berkelium (Bk), californium (Cf), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), titanium (Ti), vanadium (V), chromium (Cr), manganese (Mn), yttrium (Y), zirconium (Zr), niobium (Nb), molybdenum (Mo), hafnium (Hf), tantalum (Ta) tungsten (W), rhenium (Re) or their isotopes, and
X is at least one of hydrogen (H), fluorine (F), chlorine (CI), bromine (Br), iodine (I), oxygen (O), sulfur(S), selenium (Se), tellurium (Te), nitrogen (N), phosphorus (P), arsenic (As), antimony (Sb), carbon (C), silicon (Si), germanium (Ge), boron (B) and their isotopes;
and n is selected from any number from 0.05 to 20.

10. The apparatus of claim 9, wherein the formula II further includes a dopant selected from at least one of nitrogen or boron.

11. The apparatus of claim 1, wherein the low resistance material includes at least one of a pure cuprate superconductor or a doped cuprate superconductor.

12. The apparatus of claim 1, wherein the low resistance material includes at least one of yttrium barium copper oxide or bismuth strontium calcium copper oxide.

13. The apparatus of claim 1, wherein the low resistance material includes a chiral superconductor.

14. The apparatus of claim 13, wherein the chiral superconductor comprises rhombohedral stacked multilayer graphene.

15. The apparatus of claim 14, wherein the rhombohedral stacked multilayer graphene includes at least one of tetra-layer or penta-layer graphene.

16. The apparatus of claim 1, wherein the conductor layer includes a plurality of layers disposed radially one top of each other, at least one layer of the plurality of layers including the low resistance material.

17. The apparatus of claim 16, wherein:
the at least one layer includes an inner layer of the conductor layer, and
one or more outer layers of the conductor layer disposed around the inner layer and configured to exert a pressure on the inner layer.

18. The apparatus of claim 1, wherein the encapsulation layer includes a conductive material.

19. A method, comprising:
forming a core including a composite material;
disposing an encapsulation layer on the core to form a strength member; and
disposing one or more layers on the strength member, at least one layer of the one or more layers including a conductor having a resistivity of less than 10⁻¹⁰ Ω·cm over an operating temperature in a range of about −40 degrees Celsius about 250 degrees Celsius.

20. The method of claim 19, further comprising:
treating outer surface of the one or more layers disposed on the strength member.

21. The method of claim 20, wherein treating the outer surface of the one or more layers causes the outer surface to have a solar absorptivity of less than 0.6.

22. The method of claim 19, further comprising:
disposing a pressurizing layer on the one or more layer disposed on the strength member.

23. The method of claim 19, further comprising:
disposing an insulator layer on the one or more layer disposed on the strength member.

24. The method of claim 19, wherein the conductor includes a superconductor or superconductor-like material.

25. The method of claim 24, wherein the superconductor includes a chiral superconductor, the chiral superconductor comprising at least one of rhombohedral tetra-layer or rhombohedral penta-layer graphene.

26. The method of claim 19, wherein disposing the one or more layers on the strength member comprises:
disposing a first layer including a first set of conductive strands in a first wound direction around the strength member,
disposing a second layer including a second set of conductive strands in a second wound direction around the first layer, the second wound direction being opposite to the first wound direction; and
optionally disposing a third layer including a third set of conductive strands in the first wound direction around the second layer.
